(19) United States
(12) Patent Application Publication
(10) Pub. No.: US 2001/0012222 A1
(43) Pub. Date: Aug. 9, 2001

(54) Memory controller for flash memory system and method for accessing flash memory device

(76) Inventor: Yukio Terasaki, Tokyo (JP)

Correspondence Address: Brown Raysman Millstein Felder & Steiner LLP, Suite 711, 1880 Century Park East, Los Angeles, CA, 90067, US

(21) Appl. No.: 09/740,919

(22) Filed: Dec. 19, 2000

(30) Foreign Application Priority Data
Dec. 20, 1999 (JP) 11-360393
Jun. 22, 2000 (JP) 2000-187184

(51) Int. Cl. G11C 7/00

(52) U.S. Cl. 365/200

(57) ABSTRACT

A memory controller having an address translation table whose memory capacity is reduced is disclosed. The memory controller according to the present invention has an address translation table 27 composed of scopes 0 to 3 and a management table 28 indicating that each of the scopes 0 to 3 storing which area's address translating information. One of the scopes 0 to 3 is selected based on upper 5 bits of a host address supplied from a host computer. A logical block address included in the host address is converted into a physical block address with reference to address translating information stored in the selected scope.

### BACKGROUND OF THE INVENTION

The present invention relates to a memory controller for a flash memory system, a flash memory system and a method for accessing a flash memory device, and particularly, to such a memory controller and a flash memory system employing an address translation table having relatively small capacity and a method for accessing a flash memory device using an address translation table having relatively small capacity.

### DESCRIPTION OF THE PRIOR ART

In recent years, flash memory devices are widely used as semiconductor memory devices for memory cards, silicon disks and the like. In such a flash memory device, although a transition from an erased state to a programmed state can be performed for each memory cell as an individual unit, a transition from the programmed state to the erased state cannot be performed for each memory cell as an individual unit. Such a transition from the programmed state to the erased state can be only performed for a predetermined number of memory cells as a unit, called a “block”, constituted of a plurality of memory cells.

According to the flash memory device, because the transition from the programmed state to the erased state can be only performed in block units, in order to write new data into a certain block in which other data are already written, it is required to change the states of all memory cells included in the block to the erased state and then write new data into the block. Therefore, in the case where new data are overwritten into a certain block in which other data are already written, the other data must be transferred to another block in order to avoid destruction of the other data.

Thus, when a command to overwrite new data into a certain block in which other data are already written is issued from a host computer, the new data and data which should not be overwritten among data contained in the block are stored into a new unused block, and the states of all memory cells included in the old block are then changed to the erased state, whereby the old block becomes an unused block.

According to the flash memory device, the new data and data which should not be overwritten among data contained in the old block must be relocated to another block each time a command to overwrite new data is issued from the host computer. Therefore, the relationship between a logical address supplied from the host computer and a physical address corresponding to the logical address is actively changed each time a command to overwrite new data is issued from the host computer. Thus, an address translation table for converting the logical address supplied from the host computer to the physical address corresponding to the logical address is required for the flash memory system.

FIG. 1 is a schematic diagram showing a conventional flash memory system 31.

As shown in FIG. 1, the flash memory system 31 is composed of an address translation table 32 and a flash memory device 33.

The address translation table 32 includes a plurality of storing units 34-1 to 34-13 assigned logical addresses 0001 to 0013. The physical addresses corresponding to the logical addresses 0001 to 0013 are stored in the storing units 34-1 to 34-13, respectively.

The flash memory device 33 is composed of a plurality of blocks 35-0 to 35-12 assigned the physical addresses 0000 to 0012, respectively. Each of the blocks 35-0 to 35-12 is composed of a user area 36 and a redundant area 37, each of which includes a plurality of memory cells. The user area 36 is an area adapted to store user data, and the redundant area 37 is an area adapted to store a logical address corresponding thereto. Each block 35-0 to 35-12 constitutes a unit to be flash erased.

When the logical address is supplied from the host computer (not shown) to the conventional flash memory system 31 having the above mentioned configuration, first, the physical address is read from the storing unit assigned the logical address supplied from the host computer among the storing units 34-1 to 34-13 constituting the address translation table 32. For example, if the logical address supplied from the host computer is “0009”, the physical address “0001” is read from the storing unit 34-9 assigned to the given logical address “0009”. Next, the block among the blocks 35-0 to 35-12 constituting the flash memory device 33 assigned the physical address read from the address translation table 32 is accessed. For example, if the physical address read from the address translation table 32 is “0001”, the block 35-1 assigned the physical address “0001” is accessed.

In this flash memory system, as mentioned above, the relationship between the logical address supplied from the host computer and the physical address corresponding to the logical address can be actively changed using the address translation table 32.

In recent years, however, as the capacity of flash memory devices has gradually increased, the number of the blocks each constituting a unit to be flash erased has also gradually increased. Therefore, according to the conventional flash memory system 31, the memory capacity required for the address translation table 32 inevitably has to be increased in proportion to the increase in the number of blocks included in the flash memory device 33.

Moreover, the address translation table 32 is generally stored in an SRAM (static random access memory) area located in the memory controller. It is difficult to increase the degree of integration because many transistors are required per SRAM cell, while the access speed is very fast in the SRAM. Thus, when the memory capacity required for the address translation table 32 increases, the chip area of the memory controller which controls the flash memory device also increases. As a result, it is difficult to reduce the cost of the flash memory system 31.

### SUMMARY OF THE INVENTION

It is therefore an object of the present invention to provide an improved memory controller for a flash memory system, an improved flash memory system and a method for accessing a flash memory device.

Another object of the present invention is to provide a memory controller having an address translation table whose memory capacity is reduced.

A further object of the present invention is to provide a method for accessing a flash memory device using an address translation table whose memory capacity is reduced.

The above and other objects of the present invention can be accomplished by a memory controller for accessing a memory divided into a plurality of areas based on a host address supplied from a host computer comprising an address translation table constituted of a plurality of scopes each of which stores a piece of address translating information corresponding to one of said areas of said memory, each piece of said address translating information being composed of a plurality of converted addresses, said memory controller further comprising selecting means for selecting one of said scopes from said address translation table based on a first portion of said host address, reading means for reading out one converted address from said address translation information stored in the selected scope based on a second portion of said host address, and access means for accessing the memory based on at least the thus read-out converted address, the number of said scopes of said address translation table being smaller than that of said areas of said memory.

According to this aspect of the present invention, the memory capacity of the address translation table can be reduced because the number of scopes of the address translation table is smaller than that of the areas of the memory.

In a preferred aspect of the present invention, the memory controller further comprises replace means for replacing, in response to the fact that said address translating information corresponding to an area selected by said first portion of said host address is not stored in any scopes of said address translation table, said address translating information stored in one of said scopes with address translating information corresponding to said area selected by said first portion of said host address.

In a further preferred aspect of the present invention, the memory controller further comprises scope determination means for determining a scope to be replaced by said replacing means based on an access history.

According to this preferred aspect of the present invention, the contents of a certain scope storing address translating information corresponding to the area whose access frequency is low can be replaced with new address translating information corresponding to the area selected by said first portion of said host address prior to replacing the contents of other scopes, because the scope whose contents are to be replaced is determined based on an access history.

In a further preferred aspect of the present invention, each of said areas is divided into a plurality of blocks each of which is composed of a plurality of flash memory cells, said converted address being used to select one of said blocks, each of said blocks constituting a unit to be flash-erased.

In further preferred aspect of the present invention, said access means accesses said memory based on at least said read-out converted address and a third portion of said host address.

In a further preferred aspect of the present invention, each of said blocks is divided into a plurality of pages, said third portion of said host address being used to select one of said pages included in said block selected by said converted address, each of said pages constituting a unit to be accessed.

In a further preferred aspect of the present invention, said access means accesses said memory based on at least said read converted address and said first and third portions of said host address.

The above and other objects of the present invention can be also accomplished by a flash memory system comprising a flash memory and a memory controller for accessing said flash memory based on a host address including at least an area address and a logical block address and supplied from a host computer, said flash memory being divided into a plurality of areas, each of said areas being selected by said area address of said host address and divided into a plurality of blocks, each of said blocks being selected by a physical block address, said memory controller further comprising an address translation table which is divided into a plurality of scopes, a management table storing a relationship between said scopes and said areas of said flash memory, judgment means for judging whether or not address translating information for said area selected by said area address is stored in one of said scopes of said address translation table by referring to said management table, replace means for replacing said address translating information stored in one of said scopes with address translating information for said area selected by said area address when said address translating information for said area selected by said area address is not stored in any scopes of said address translation table, converting means for converting said logical block address of said host address into said physical block address by referring to said scope storing said address translating information for said area selected by said area address, and access means for accessing said flash memory based on at least said logical block address, each of said scopes storing address translating information indicating relationships between said logical block addresses and said physical block addresses, the number of said scopes being smaller than that of said areas of said flash memory.

According to this aspect of the present invention, the memory capacity of the address translation table can be reduced because the number of the scopes of the address translation table is smaller than that of the areas of the flash memory.

In a preferred aspect of the present invention, said flash memory and said memory controller are enclosed in the same package.

In a further preferred aspect of the present invention, said package is card-shaped.

In a further preferred aspect of the present invention, said host address is composed of at least said area address, said logical block address and a page address, and each of said blocks is divided into a plurality of pages which are selected by said page addresses.

In a further preferred aspect of the present invention, each of said blocks constitutes a unit to be flash-erased.

In a further preferred aspect of the present invention, each of said pages constitutes a unit to be accessed.

In a further preferred aspect of the present invention, each of said pages includes a user area and a redundant area, and said redundant area stores an error correction code for correcting an error of user data stored in said user area.

In a further preferred aspect of the present invention, said memory controller further comprises a priority link for indicating which scope is the least significant.

In a further preferred aspect of the present invention, said replacing means replaces said address translating information stored in said scope which is indicated as the least significant scope by said priority link with address translating information for said area selected by the area address.

In a further preferred aspect of the present invention, said flash memory includes a plurality of flash memory cells, each of which can store more than 2 bits.

The above and other objects of the present invention can be also accomplished by a method for accessing a flash memory divided into m areas comprising the steps of receiving a host address supplied from a host computer, selecting one of n (n<m) scopes constituting an address translation table based on a first portion of said host address, converting a second portion of said host address into a converted address based on address translating information read from the selected scope, and accessing said flash memory based on at least said converted address.

According to this aspect of the present invention, the memory capacity of the address translation table can be reduced because the number of the scopes (n) of the address translation table is smaller than that of the areas (m) of the flash memory.

In a further preferred aspect of the present invention, the method for accessing a flash memory further comprises the step of replacing said address translating information stored in one of said scopes with address translating information corresponding to said area selected by said first portion of said host address when said address translating information corresponding to an area selected by said first portion of said host address is not stored in any scopes of said address translation table.

In a further preferred aspect of the present invention, the method for accessing a flash memory further comprises the step of determining a scope to be replaced during said replacing step based on an access history.

The above and other objects and features of the present invention will become apparent from the following description made with reference to the accompanying drawings.

### BRIEF DESCRIPTION OF THE DRAWINGS

FIG. 1 is a schematic diagram showing the conventional flash memory system 31.

FIG. 2 is a schematic block diagram showing a flash memory system 1 which is a preferred embodiment of the present invention.

FIG. 3 is a schematic sectional diagram showing a cross-section of the flash memory cell 16 included in the flash memory chips 2-0 to 2-3.

FIG. 4 is a schematic sectional diagram showing a cross-section of the flash memory cell 16 in the programmed state.

FIG. 5 is a schematic diagram showing the structure of the address space of the flash memory chip 2-0.

FIG. 6 is a schematic diagram showing the data structure of the address translation table 27 which is stored in the SRAM work area 8.

FIG. 7 is a schematic diagram showing the data structure of the management table 28 which is stored in the SRAM work area 8.

FIG. 8 is a schematic diagram showing the data structure of the priority link 29 which is stored in the SRAM work area 8.

FIG. 9 is a schematic diagram showing the priority order of scope 0→scope 1→scope 2→scope 3 by the priority link 29.

FIG. 10 is a schematic diagram showing the priority order of scope 2→scope 0→scope 1→scope 3 by the priority link 29.

FIG. 11 is a schematic diagram showing the priority order of scope 3→scope 2→scope 0→scope 1 by the priority link 29.

FIG. 12 is a schematic diagram showing the priority order of scope 1→scope 3→scope 2→scope 0 by the priority link 29.

FIG. 13 is a schematic diagram showing the data structure of the erased block queue 30 which is stored in the SRAM work area 8.

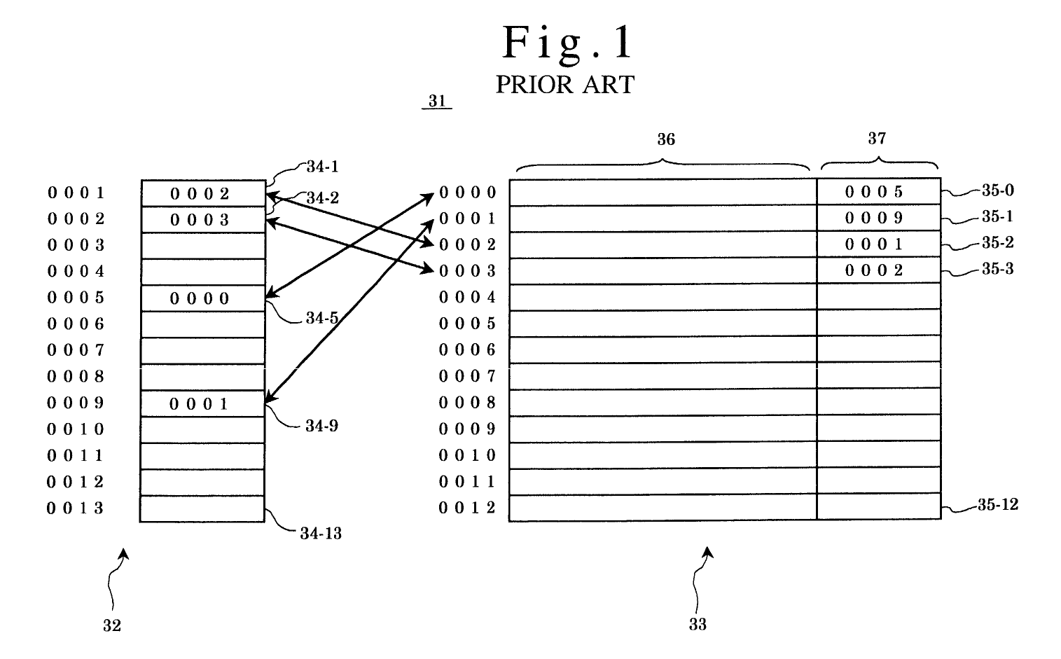

### DESCRIPTION OF THE PREFERRED EMBODIMENT

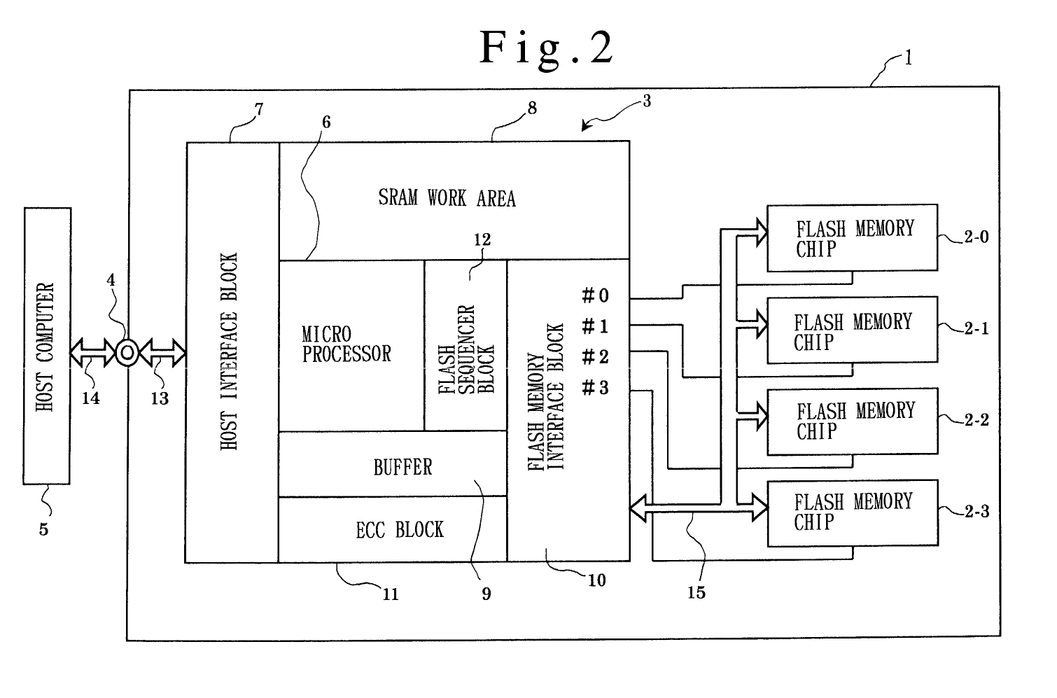

As shown in FIG. 2, the flash memory system 1 has the shape of a card, and is composed of four flash memory chips 2-0 to 2-3, a controller 3, and a connector 4, each of which is integrated into the card. The flash memory system 1 can be removably attached to a host computer 5 for use as a kind of an external storage device for the host computer 5. The host computer 5 can be a device such as a personal computer for processing various information such as text data, sound data, and video data and digital still camera data.

Each flash memory chip 2-0 to 2-3 is a semiconductor chip having a capacity of 128M bytes (1G bits). In the flash memory system 1, each page, which is a minimum access unit, is composed of 512 bytes. Thus, an address space of each flash memory chip 2-0 to 2-3 includes 256K pages, and the amount of address space of the flash memory chips 2-0 to 2-3 is 1M pages. In the flash memory system 1, these four flash memory chips 2-0 to 2-3 are treated as a big single memory having a capacity of 512M bytes (4G bits) and 1M pages of address space. Address information of 20-bit length is required to access such a memory having 1M pages of address space. Thus, to access an individual page, the host computer 5 provides address information of 20-bit length to the flash memory system 1. Such address information of 20-bit length provided from the host computer 5 to the flash memory system 1 is referred as a “host address”.

The controller 3 is composed of a microprocessor 6, a host interface block 7, a SRAM work area 8, a buffer 9, a flash memory interface block 10, an ECC (error correction code) block 11, and a flash sequencer block 12. These functional blocks composing the controller 3 are integrated in a single semiconductor chip.

The microprocessor 6 is a functional block which controls the operations of each functional block composing the controller 3.

The host interface block 7 is connected to the connector 4 via a bus 13 to send or receive data, address information, status information, and external command information to/from the host computer 5 under the control of the microprocessor 6. Specifically, when the flash memory system 1 is attached to the host computer 5, the flash memory system 1 and the host computer 5 are electrically connected to each other via the bus 13, the connector 4, and the bus 14. When the electrical connection between the flash memory system 1 and the host computer 5 is established, various information such as data provided from the host computer 5 to the flash memory system 1 is input to the controller 3 via the host interface block 7 as an input part, and various information such as data provided from the flash memory system 1 to the host computer 5 is output from the controller 3 via the host interface block 7 as an output part.

The SRAM work area 8, composed of a plurality of SRAM cells, is a working area for temporarily storing data is used by the microprocessor 6 for controlling the flash memory chips 2-0 to 2-3.

The buffer 9 is for temporarily storing data read from the flash memory chips 2-0 to 2-3 and data to be written into the flash memory chips 2-0 to 2-3. Specifically, data read from the flash memory chips 2-0 to 2-3 are temporarily stored in the buffer 9 until the host computer 5 becomes ready to receive them, and data to be written into the flash memory chips 2-0 to 2-3 are temporarily stored into the buffer 9 until the flash memory chips 2-0 to 2-3 become ready to be written.

The flash memory interface block 10 is a functional block for sending or receiving data, address information, status information, and internal command information to/from the flash memory chips 2-0 to 2-3 via a bus 15 and for supplying the chip selection signals #0 to #3 to the flash memory chips 2-0 to 2-3. One of the chip selection signals #0 to #3 is activated in response to the upper two bits of the host address provided from the host computer 5 when a data read operation or a data write operation is requested by the host computer 5. Specifically, the chip selection signals #0 is selectively activated in response to the upper two bits of the host address being “00”, the chip selection signals #1 is selectively activated in response to the upper two bits of the host address being “01”, the chip selection signals #2 is selectively activated in response to the upper two bits of the host address being “10”, and the chip selection signals #3 is selectively activated in response to the upper two bits of the host address being “11”. Each of the chip selection signals #0 to #3 activates a corresponding flash memory chip 2-0 to 2-3 to allow the data read operation and the data write operation to be performed. It is noted that the “internal command information” is distinguished from the “external command information”: the internal command information is issued from the controller 3 to control the flash memory chips 2-0 to 2-3; the external command information is issued from the host computer 5 to control the flash memory system 1.

The ECC block 11 is a functional block for generating an error correction code to be added to data to be written to the flash memory chips 2-0 to 2-3 and to correct any error included in data read from the flash memory chips 2-0 to 2-3.

The flash sequencer block 12 is a functional block for controlling a data transport between the flash memory chips 2-0 to 2-3 and the buffer 9. The flash sequencer block 12 has a plurality of registers (not shown). When a certain value necessary for reading data from the flash memory chips 2-0 to 2-3 or to write data into the flash memory chips 2-0 to 2-3 is set in the registers (not shown) under the control of the microprocessor 6, the flash sequencer block 12 performs certain operations necessary to read data or to write data.

Next, the physical structure of each of the flash memory cells included in the flash memory chips 2-0 to 2-3 will be explained.

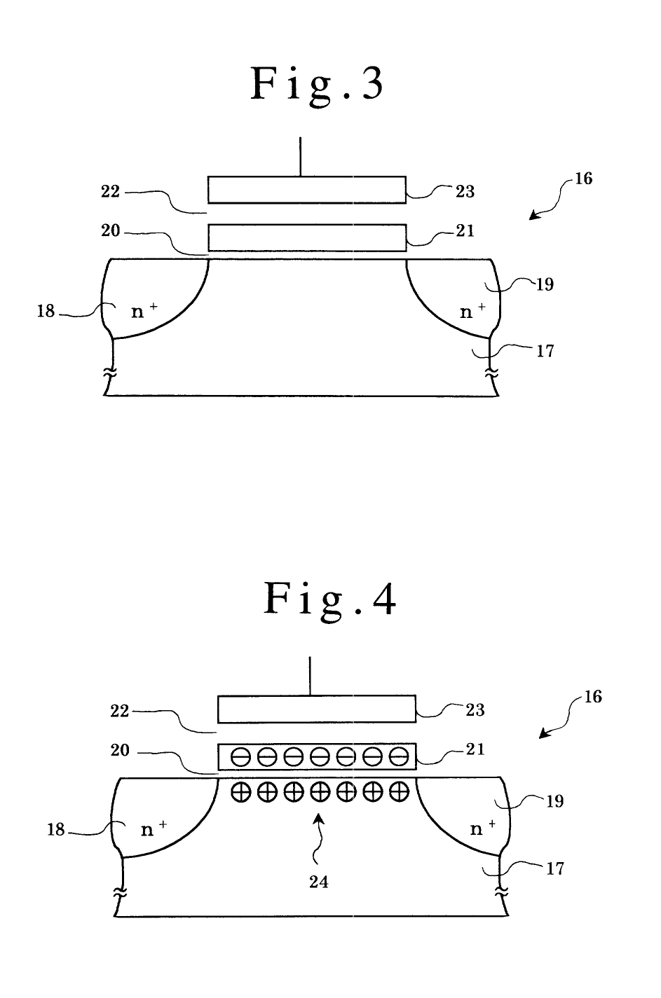

FIG. 3 is a schematic sectional diagram showing a cross-section of a flash memory cell 16 included in the flash memory chips 2-0 to 2-3.

As shown in FIG. 3, the flash memory cell 16 is composed of a semiconductor substrate 17 of p-type, the source and drain diffusion regions 18 and 19 of n-type each of which is formed in the semiconductor substrate 17, the tunnel oxide film 20 formed on a part of the semiconductor substrate 17 located between the source and drain diffusion regions 18 and 19, a floating gate electrode 21 formed on the tunnel oxide film 20, an insulating film 22 formed on the floating gate electrode 21, and a control gate electrode 23 formed on the insulating film 22. In the flash memory chips 2-0 to 2-3, pluralities of the flash memory cells 16 having the above-mentioned structure are serially connected to form a flash memory of NAND type.

The flash memory cell 16 exhibits either an “erased state” or a “programmed state” depending on whether electrons are injected into the floating gate electrode 21. The flash memory cell 16 being in the erased state indicates that the data stored therein is “1”, and the flash memory cell 16 being in the programmed state indicates that the data stored therein is “0”. That is, each flash memory cell 16 can store one bit of digital data.

As shown in FIG. 3, in the erased state, substantially no electrons are injected into the floating gate electrode 21. In the erased state, when reading voltage is not applied to the control gate electrode 23, no channel is induced at the surface of the semiconductor substrate 17 of p-type located between the source and drain diffusion regions 18 and 19, so that the source and drain diffusion regions 18 and 19 are electrically isolated from each other by the semiconductor substrate 17 of p-type. On the other hand, when reading voltage is applied to the control gate electrode 23, a channel (not shown) is induced at the surface of the semiconductor substrate 17 of p-type located between the source and drain diffusion regions 18 and 19, so that the source and drain diffusion regions 18 and 19 are electrically connected to each other by the channel (not shown). That is, no application of the reading voltage to the control gate electrode 23 causes the source and drain diffusion regions 18 and 19 to be electrically isolated from each other, and application of the reading voltage to the control gate electrode 23 causes the source and drain diffusion regions 18 and 19 to be electrically connected to each other.

FIG. 4 is a schematic sectional diagram showing a cross-section of the flash memory cell 16 in the programmed state.

As shown in FIG. 4, in the programmed state, electrons are injected into the floating gate electrode 21. The electrons injected into the floating gate electrode 21 stay therein for an extremely long period because the floating gate electrode 21 is sandwiched between the tunnel oxide film 20 and the insulating film 22. In the programmed state, a channel 24 is induced at the surface of the semiconductor substrate 17 of p-type located between the source and drain diffusion regions 18 and 19 regardless of whether reading voltage is being applied to the control gate electrode 23. Therefore, the source and drain diffusion regions 18 and 19 are always electrically connected to each other by the channel 24 regardless of whether reading voltage is being applied to the control gate electrode 23.

It can be detected whether the flash memory cell 16 is in the erased state or the programmed state by the following steps. First, reading voltage is applied to every control gate electrode 23 of the flash memory cells 16 except for the selected flash memory cell 16, so that the flash memory cells 16 are serially connected to form a serial circuit. Next, it is detected whether or not current can flow through the serial circuit. Then, the state of the selected flash memory cell 16 is judged to be in the programmed state if current can flow through the serial circuit, and the state of the selected flash memory cell 16 is judged in the erased state if current cannot flow through the serial circuit. In this manner, the data stored in each flash memory cell 16 can be read out. In the flash memory of NAND type, however, two or more data stored in flash memory cells 16 which belong to the same serial circuit cannot be read out simultaneously.

To change the state of the flash memory cell 16 from the erased state to the programmed state, high positive voltage is applied to the control gate electrode 23 to inject electrons into the floating gate electrode 21 via the tunnel oxide film 20. The injection of the electrons into the floating gate electrode 21 can be performed using an F-N tunnel current. On the other hand, to change the state of the flash memory cell 16 from the programmed state to the erased state, high negative voltage is applied to the control gate electrode 23 to eject the previously injected electrons from the floating gate electrode 21 via the tunnel oxide film 20.

Next, the specific structure of the address space of each of the flash memory chips 2-0 to 2-3 will be explained.

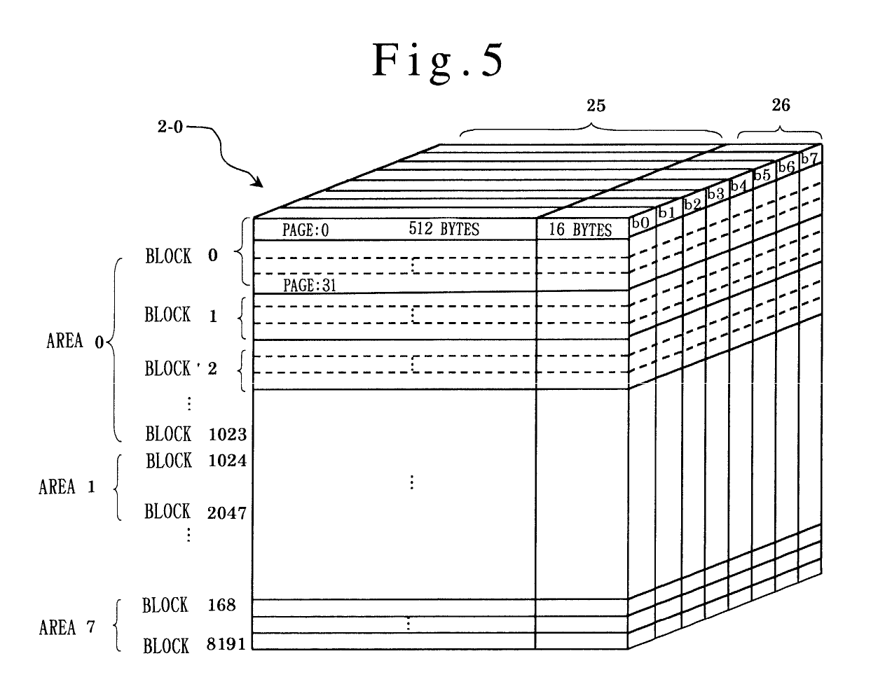

FIG. 5 is a schematic diagram showing the structure of the address space of the flash memory chip 2-0.

As shown in FIG. 5, the address space of the flash memory chip 2-0 is divided into eight areas composed of areas 0 to 7. Although not shown in FIG. 5, each of the address spaces of the flash memory chips 2-1 to 2-3 is also divided into eight areas: the address space of the flash memory chip 2-1 is divided into areas 8 to 15, the address space of the flash memory chip 2-2 is divided into areas 16 to 23, and the address space of the flash memory chip 2-3 is divided into areas 24 to 31. Each of the areas 0 to 31 has a memory capacity of 16M bytes.

Moreover, each area 0 to 7 composing the address space of the flash memory chip 2-0 is divided into 1024 blocks. Specifically, as shown in FIG. 5, the area 0 is composed of blocks 0 to 1023, the area 1 is composed of the blocks 1024 to 2047, and the area 7 is composed of the blocks 7168 to 8191. Therefore, the address space of the flash memory chip 2-0 is divided into 8192 blocks composed of the blocks 0 to 8191. Although not shown in FIG. 5, each of the address spaces of the flash memory chips 2-1 to 2-3 is also divided into 8192 blocks: the address space of the flash memory chip 2-1 is composed of the blocks 8192 to 16383, the address space of the flash memory chip 2-2 is composed of the blocks 16384 to 24575, and the address space of the flash memory chip 2-3 is composed of the blocks 24576 to 32767. Each of the blocks 0 to 32767 has a memory capacity of 16K bytes.

Each block 0 to 32767 is a unit of flash erasing. In other words, according to the flash memory chips 2-0 to 2-3, the state of each flash memory cell 16 cannot be changed from the programmed state to the erased state in cell units. To change the state of the flash memory cell 16 from the programmed state to the erased state, it is required to change the states of all flash memory cells 16 of the block including the flash memory cells 16 to be erased. In contrast, the state of each flash memory cell 16 can be changed from the erased state to the programmed state in cell units.

Further, as shown in FIG. 5, each block 0 to 8191 composing the flash memory chip 2-0 is divided into 32 pages assigned the page addresses 0 to 31, respectively. Similar to the blocks 0 to 8191 composing the flash memory chip 2-0, each block 8192 to 32767 composing the flash memory chips 2-1 to 2-3 is also divided into 32 pages assigned page addresses 0 to 31, respectively.

Each of the pages is an access during the read operation and the write operation and is composed of the user area 25 of 512 bytes and the redundant area 26 of 16 bytes where 1 byte is equal to 8 bits composed of bits 0to 7. The user area 25 is an area for storing user data supplied from the host computer 5 and the redundant area 26 is an area for storing additional information such as the error correction code generated by the ECC block 11. The error correction code is a piece of additional information for correcting any error included in data stored in the corresponding user area 25. If the number of errors included in data stored in the user area 25 is smaller than a certain number, the errors are corrected by using the error correction code stored in the corresponding redundant area 26.

The host computer 5 supplies the host address to the flash memory system 1, which employs the flash memory chips 2-0 to 2-3 having the above-mentioned structure, to request read operation and write operation of individual pages as access units composed of 512 bytes. Because each page is composed of the user area 25 of 512 bytes and the redundant area 26 of 16 bytes, each page includes 8×(512 bytes+16 bytes)=4224 flash memory cells.

Because the flash memory chips 2-0 to 2-3 having the above-mentioned structure are treated as a big single memory having 1M pages of address space, address information of 20-bit length is required to access individual pages included in the address space. Among the 20 bits, the upper 5 bits are used to select a particular area to be accessed among the 32 areas composed of the areas 0 to 31, 10 bits composed of the upper 6 bit to 15 bit are used to select a particular block to be accessed among the 1024 blocks composing the selected area, and the remaining lower 5 bits are used to select a particular page to be accessed among the 32 pages composing the selected block. As explained in further detail later, the area and the page to be accessed can be univocally decided by the upper 5 bits and the lower 5 bits of the host address supplied from the host computer 5, but the block to be accessed cannot be univocally decided by the 10 bits composed of the upper 6 bit to 15 bit of the host address supplied from the host computer 5. The 10 bits composed of the upper 6 bit to 15 bit of the host address are referred as a “logical block address” and the physical address of the block to be accessed is referred as a “physical block address” which is not the same as the logical block address. The logical block address is converted into the physical block address by referring to an address translation table which will be explained later, whereafter the specific block assigned such a physical block address is accessed.

The need for converting the logical block address into the physical block address by referring to the address translation table will be explained.

As mentioned above, although the state of each flash memory cell 16 composing the flash memory chips 2-0 to 2-3 can be changed from the erased state to the programmed state in cell units, the state of the flash memory cells 16 cannot be changed from the programmed state to the erased state in cell units, the state change can be only performed in block units. Thus, to store new data into a certain page, it is required that every flash memory cell 16 composing the user area 25 of the page be in the erased state. In other words, if even a single flash memory cell 16 included in the page into which data are stored is in the programmed state, overwriting of other data into such a page cannot be directly performed. Therefore, to overwrite new data into such a page already storing other data a flash erasing operation must be performed in advance to change the states of all of the flash memory cells 16 of the block including the page into which data are to be overwritten to the erased state, whereafter new data are written into the page.

Therefore, in case of overwriting new data into a certain page already storing other data, the data already stored in other pages belonging to the same block must be moved to other pages belonging to another block in order to avoid destruction of such data. Hence, the relationship between the logical block address included in the host address and the physical block address assigned to each block of the flash memory chips 2-0 to 2-3 corresponding to the logical block address is actively changed each time an overwrite operation is requested by the host computer 5. Thus, to access the flash memory chips 2-0 to 2-3 from the host computer 5, an address translation table for converting the logical block address provided from the host computer 5 into the physical block address corresponding to the logical block address is required. The address translation table will be specifically explained later.

In the redundant area 26 of the top page (page 0) of each block, not only the error correction code but also an erase flag and a corresponding logical block address are stored. The erase flag is a flag indicating whether or not all of the flash memory cells 16 composing the user areas 25 of the block are in the erased state, i.e., indicating whether or not the block is an erased block, and the corresponding logical block address indicates by what logical block address the block is accessed. The corresponding logical block address is stored in case some data are stored in the block, i.e., when the erase flag indicates that the block is not an erased block. The erase flag and the corresponding logical block address will be explained in detail later.

Next, various working data stored in the SRAM work area 8 will be explained. At least an address translation table 27, a management table 28, a priority link 29, and an erased block queue 30 are stored in the SRAM work area 8.

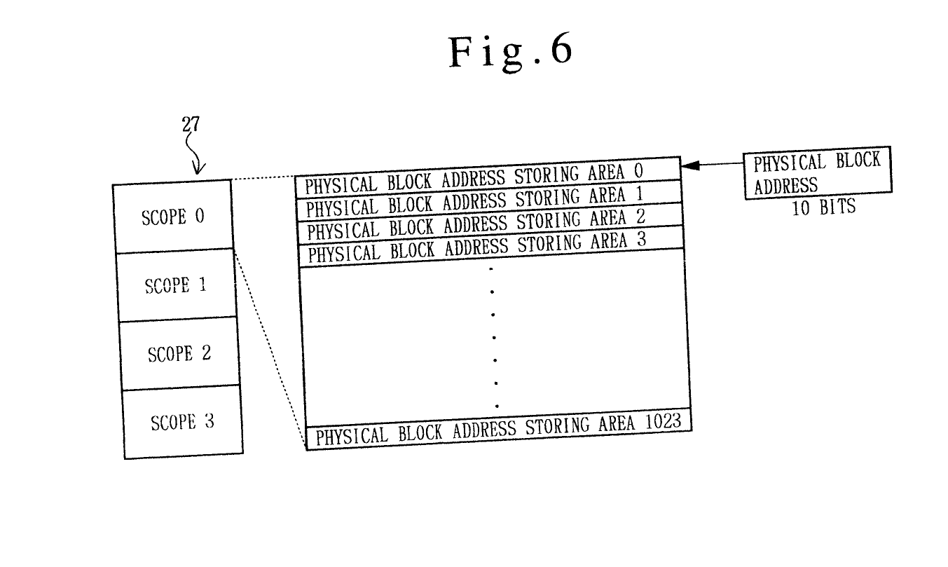

FIG. 6 is a schematic diagram showing the data structure of the address translation table 27 stored in the SRAM work area 8.

As shown in FIG. 6, the address translation table 27 is composed of scopes 0 to 3, each of which has 1024 physical block address storing areas. For example, as shown in FIG. 6, the scope 0 is composed of the physical block address storing areas 0 to 1023. Similarly, although not shown in FIG. 6, the scope 1 is composed of the physical block address storing areas 1024 to 2047, the scope 2 is composed of the physical block address storing areas 2048 to 3071, and the scope 3 is composed of the physical block address storing areas 3072 to 4095.

In the physical block address storing areas 0 to 4095, corresponding physical block addresses are stored, so that each of the scopes 0 to 3 indicates address translating information of a corresponding area. Specifically, the logical block addresses 0 to 1023 are assigned to the 1024 physical block address storing areas of each of the scopes 0 to 3, so that each of the physical block addresses stored in the physical block address storing areas is related to the logical block address assigned thereto. For example, if the logical block address (10 bits composed of the upper 6 bit to 15 bit of the host address) supplied from the host computer 5 is 0101010101B, the physical block address storing area assigned 341 as the logical block address is selected, and the physical block address stored therein is read out. If the read physical block address is for example 0000011111B, the physical block address to be accessed is decided to be 31, so that conversion of the logical block address 341 into the physical block address 31 is completed.

The relationship between scopes 0 to 3 and areas 0 to 31 is indicated by the management table 28, explained later. The number of the scopes (4) included in the address translation table 27 is smaller than the number of the areas (32) included in the flash memory chips 2-0 to 2-3. This means that the address translation table 27 does not have all address translating information for the flash memory chips 2-0 to 2-3, but has only a part of the address translating information, only for 4 areas in the scopes 0 to 3.

Each of the physical block address storing areas 0 to 4095 occupies 10 bits of the SRAM work area 8 to store the physical block address. Thus, the address translation table 27 occupies 5.12K bytes (40960 bits) of the SRAM work area 8.

The address translation table 27 is generated in the following manner.

As mentioned above, not only the error correction code generated by the ECO block 11 but also the “corresponding logical block address”, which indicates the logical block address by which the block is accessed, is stored in the redundant area 26 of the top page (page 0) of the block which stores data. Because it can be detected whether the block stores data or not by referring to the “erase flag”, a search operation is performed under the control of the microprocessor 6 to detect the blocks storing data by checking their erase flags, and the corresponding logical block addresses are read from the redundant area 26 of the top page (page 0) of the block storing data via the flash memory interface block 10. Then, the physical block addresses are stored in the physical block address storing areas assigned the same logical block addresses as the read corresponding logical block addresses. For example, if the physical block address of a certain block is “10” and the corresponding logical block address stored therein is “123,” “10” is stored as the physical block address in the physical block address storing area assigned “123” as the logical block address. Then, address translating information according to the certain block, whose physical block address is “10”, of the certain area is completed.

Such an operation is performed for each block which contains data among all blocks composing the certain area, so that each of the physical block addresses assigned to such blocks that contains data are stored into corresponding physical block address storing areas composing the certain scope.

Then, above mentioned operation is performed for 4 areas, so that each of the corresponding physical block addresses is stored into each of the physical block address storing areas composing four scopes, and then, the generating operation of the address translation table 27 is completed. the relationship between 32 areas and 4 scopes is indicated by the management table 28.

Next, the data structure of the management table 28 stored in the SRAM work area 8 will be explained.

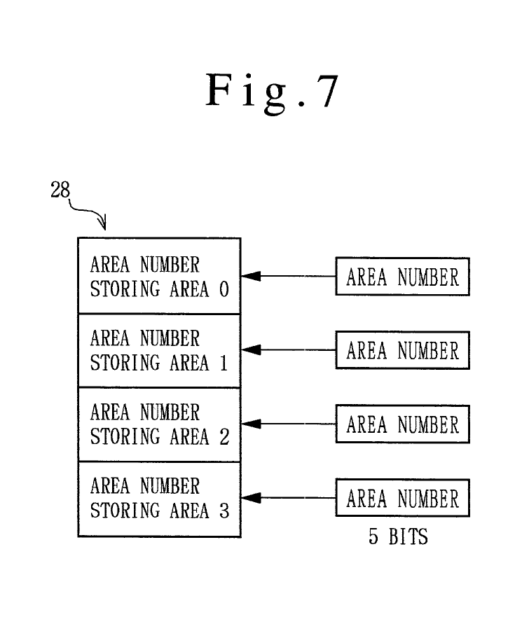

FIG. 7 is a schematic diagram showing the data structure of the management table 28 stored in the SRAM work area 8.

As shown in FIG. 7, the management table 28 is composed of the area number storing areas 0 to 3. Each of the area number storing areas 0 to 3 occupies 1 byte of the SRAM work area 8, and an area number is stored in each of the area number storing areas 0 to 3 by 5 bits data. Thus, the management table 28 occupies 4 bytes of the SRAM work area 8.

The management table 28 is a table for indicating that which address translating information is stored in the scopes 0 to 3 composing the address translation table 27. Specifically, the number stored in the area number storing area 0 is the same as the area number whose address translating information is stored in the scope 0, the number stored in the area number storing area 1 is coincident with the area number whose address translating information is stored in the scope 1, the number stored in the area number storing area 2 is the same as the area number whose address translating information is stored in the scope 2, and the number stored in the area number storing area 3 the same as the area number whose address translating information is stored in the scope 3.

The generation of the management table 28 is performed under the control of the microprocessor 6 during the generation of the address translation table 27.

Next, the data structure of the priority link 29 stored in the SRAM work area 8 will be explained.

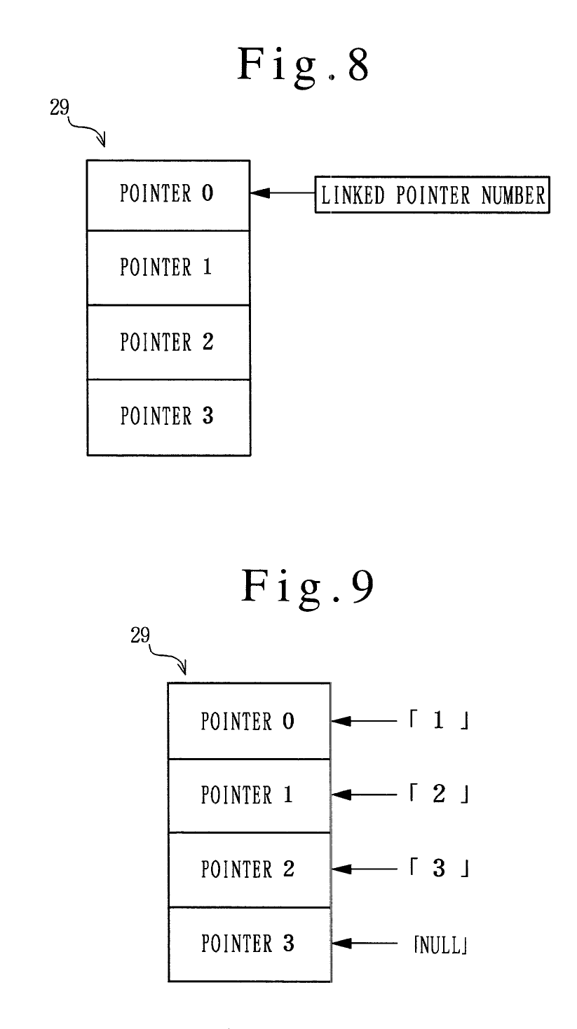

FIG. 8 is a schematic diagram showing the data structure of the priority link 29 stored in the SRAM work area 8.

As shown in FIG. 8, the priority link 29 is composed of pointers 0 to 3. Each of the pointers 0 to occupies 1 byte of the SRAM work area 8, and the linked pointer number or data “NULL” are stored in each of the pointers 0 to 3. Thus, the priority link 29 occupies 4 bytes of the SRAM work area 8.

The priority link 29 is an element for indicating the priority order among 4 scopes (scopes 0 to 3). The pointers 0 to 3 composing the priority link 29 correspond to the scopes 0 to 3 composing to the address translation table 27, respectively.

Before explaining how the priority link 29 indicates the priority order of the scopes 0 to 3 composing the address translation table 27, the necessity to prioritize the 4 scopes composing the address translation table 27 will be explained.

As mentioned above, because the number of scopes (4) composing the address translation table 27 is smaller than the number of areas (32) composing the flash memory chips 2-0 to 2-3, address translating information stored in the address translation table 27 is only part of the address translating information of all areas composing the flash memory chips 2-0 to 2-3. Therefore, if the host computer 5 requests a read operation or a write operation to with respect to an area whose address translating information is not stored in the address translation table 27, the update of the contents of the address translation table 27 is required. Specifically, the microprocessor 6 is required to select one scope among the 4 scopes composing the address translation table 27, discard the content thereof, and then stores address translating information of the area thereto. Therefore, to select one scope whose content should be canceled among the 4 scopes, prioritization of the 4 scopes composing the address translation table 27 is required, and the content of the 4 scopes is canceled in order of lower to higher priority.

For this reason, the priority order of the 4 scopes composing the address translation table 27 is required, and the priority link 29 is employed to memorize the priority order.

Next, how the priority order of the scopes 0 to 3 is memorized using the priority link 29 will be explained with reference to the drawings.

FIG. 9 is a schematic diagram showing the priority order of scope 0→scope 1→scope 2→scope 3 of the priority link 29.

As shown in FIG. 9, if the priority order is decided as scope 0→scope 1→scope 2→scope 3, the linked pointer number “1” is stored in the pointer 0, the linked pointer number “2” is stored in the pointer 1, the linked pointer number “3” is stored in the pointer 2, and data “NULL” are stored in the pointer 3.

As mentioned above, the pointers 0 to 3 composing the priority link 29 correspond to the scopes 0 to 3 composing to the address translation table 27, respectively. The pointer not pointed to by any other pointer, namely, the pointer 0, is the most significant pointer indicating that the corresponding scope (scope 0) is the most significant scope, the pointer pointed to by the pointer 0, namely, the pointer 1, is the next most significant pointer indicating that the corresponding scope (scope 1) is the next most significant scope, the pointer pointed to by the pointer 1, namely, the pointer 2, is the third most significant pointer indicating that the corresponding scope (scope 2) is the third most significant scope, and the pointer pointed to by the pointer 2, namely, the pointer 3, is the least significant pointer indicating that the corresponding scope (scope 3) is the least significant scope. In this manner, the priority order of scope 0→scope 1→scope 2→scope 3 is indicated. Data “NULL” is stored in the least significant pointer, pointer 3, which corresponds to the least significant scope.

While such a priority order is memorized in the priority link 29, if the area corresponding to the scope 2 is accessed by the host computer 5, the priority order memorized in the priority link 29 is updated such that the scope 2 becomes to be the most significant scope.

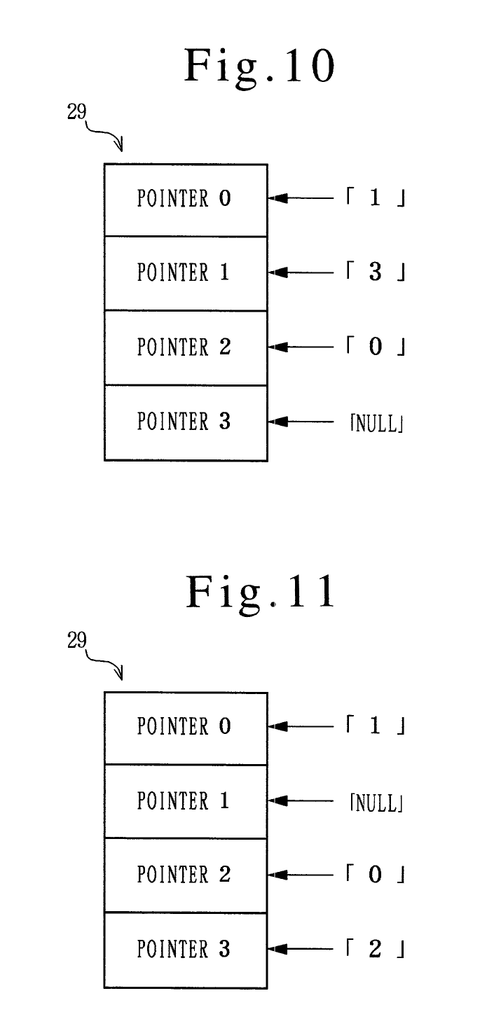

FIG. 10 is a schematic diagram showing the priority order of scope 2→scope 0→scope 1→scope 3 of the priority link 29.

As shown in FIG. 10, while the priority order is scope 2→scope 0→scope 1→scope 3, if the area corresponding to the scope 2 is accessed, the linked pointer number stored in the pointer 1 is changed to “3” and the linked pointer number stored in the pointer 2 is changed to “0” under the control of the microprocessor 6. Such operations are performed in the following manner.

At first, the content of the pointer (pointer 1), whose stored linked pointer number is the same number (2) as the scope number of the now-accessed scope (scope 2), is overwritten to the content (3) of the pointer (pointer 2) which corresponds to the now-accessed scope (scope 2). Next, the content of the pointer (pointer 2) which corresponds to the now-accessed scope (scope 2) is overwritten to the number (0) of the most significant scope (scope 0). According to these operations, the linked pointer number stored in the pointer 1 is changed to “3” and the linked pointer number stored in the pointer 2 is changed to “0”, as mentioned above.

In the priority order of the so-updated priority link 29, the pointer not pointed to by any other pointer, namely, the pointer 2, is the most significant pointer indicating that the corresponding scope (scope 2) is the most significant scope, the pointer pointed to by the pointer 2, namely, the pointer 0, is the next most significant pointer indicating that the corresponding scope (scope 0) is the next most significant scope, the pointer pointed to by the pointer 0, namely, the pointer 1, is the third most significant pointer indicating that the corresponding scope (scope 1) is the third most significant scope, and the pointer pointed to by the pointer 1, namely, the pointer 3, is the least significant pointer indicating that the corresponding scope (scope 3) is the least significant scope. In this manner, the priority order of scope 2→scope 0→scope 1→scope 3 is indicated. Data “NULL” are stored in the least significant pointer, pointer 3, which corresponds to the least significant scope.

By such operations, the priority of the scope 2, which was recently accessed, becomes the most significant, and the ensuring order follows the prior order.

Similarly, while such a priority order is memorized in the priority link 29, if the area corresponding to the scope 3 is accessed by the host computer 5, the priority order memorized in the priority link 29 is updated such that the linked pointer number stored in the pointer 1 is changed to data “NULL” and the linked pointer number stored in the pointer 3 is changed to “2”, whereby the priority order is changed to scope 3→scope 2→scope 0→scope 1.

FIG. 11 is a schematic diagram showing the priority order of scope 3→scope 2→scope 0→scope 1 of the priority link 29.

Now, an explanation will be made regarding the case where the host computer 5 requests access of an area whose address translating information is not stored in any scope composing the address translation table 27, while such a priority order is memorized in the priority link 29.

If the host computer 5 requests access of an area whose address translating information is not stored in any scope composing the address translation table 27, the address translation table 27 is updated; the content (address translating information) stored in the least significant scope is erased and address translating information of the now requested area is newly stored into the least significant scope. A search is performed to find the pointer in which data “NULL” are stored among the pointers 0 to 3 composing the priority link 29. In the exemplified case, because the pointer in which data “NULL” are stored is the pointer 1, as mentioned above, it can be detected that the priority of the scope 1 corresponding to the pointer 1 is the least significant.

The method of updating of the address translation table 27 is the same as the method of generating the address translation table 27 explained above. Specifically, after address translating information stored in the least significant scope is erased, the corresponding logical block addresses stored in the redundant area 26 included in the each of the top pages (page 0) of the used blocks of the requested area are read out via the flash memory interface block 10 under the control of the microprocessor 6. Then new address translating information according to the requested area is stored into the scope 1.

In response to the update of the address translation table 27, the management table 28 is also updated under the control of the microprocessor 6 to indicate that the scope 1 corresponds to the area which is now accessed. Moreover, the priority order indicated by the priority link 29 is also updated such that the priority of the scope 1, which was recently accessed, becomes the most significant.

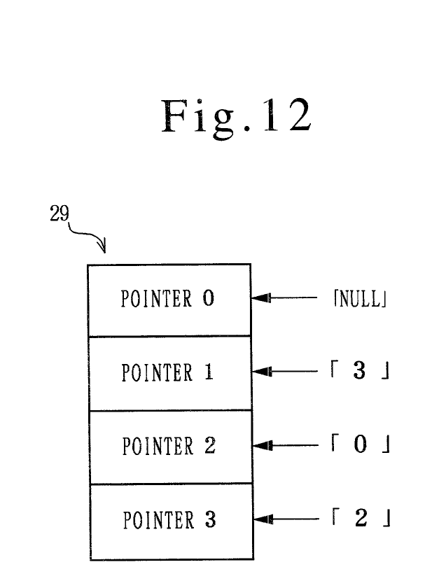

FIG. 12 is a schematic diagram showing the priority order of scope 1→scope 3→scope 2→scope 0 of the priority link 29.

As shown in FIG. 11, while the priority order is scope 3→scope 2→scope 0→scope 1, if the host computer 5 requests access an area whose address translating information is not stored in any scope composing the address translation table 27, the linked pointer number stored in the pointer 0 is changed to data “NULL” and the linked pointer number stored in the pointer 1 is changed to “3” under the control of the microprocessor 6. Such operations are performed in the same manner as explained above.

By these operations, the priority order becomes scope 1→scope 3→scope 2→scope 0. The data “NULL” are stored in the least significant pointer, pointer 0, which corresponds to the least significant scope.

As apparent from the foregoing, the priority link 29 can indicate and memorize the priority order of the scopes 0 to 3 based on the access history.

Next, the data structure of the erased block queue 30 stored in the SRAM work area 8 will be explained.

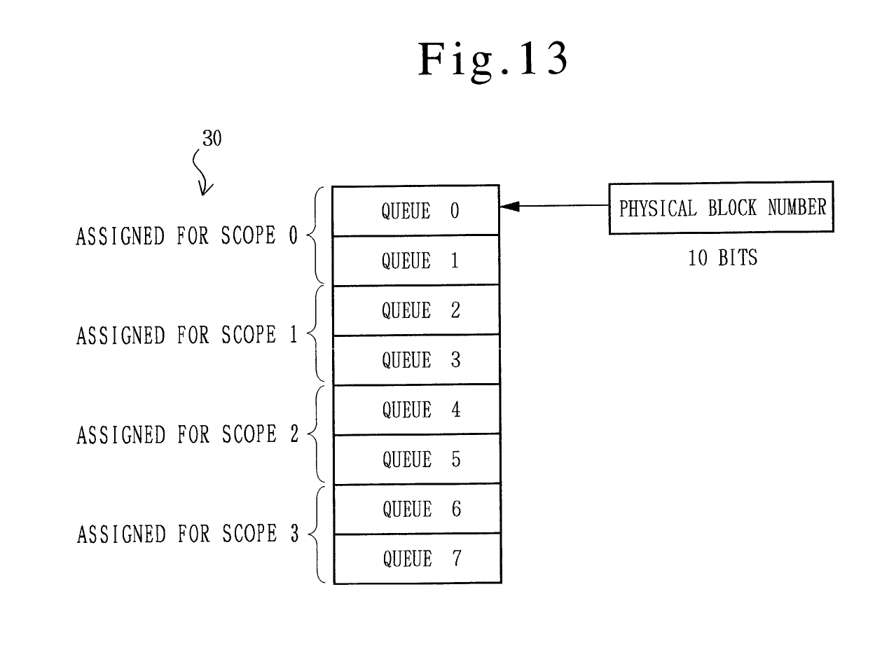

FIG. 13 is a schematic diagram showing the data structure of the erased block queue 30 stored in the SRAM work area 8.

As shown in FIG. 13, the erased block queue 30 is composed of the queues 0 to 7. Each of the queues 0 to 7 occupies 2 bytes of the SRAM work area 8, and a physical block address is stored in each of the queues 0 to 7 by 10 bits of data. Thus, the erased block queue 30 occupies 16 bytes of the SRAM work area 8.

Among the queues 0 to 7 composing the erased block queue 30, the queues 0 and 1 are assigned for the scope 0 of the address translation table 27 to store the physical block addresses of the blocks, which belong to the area corresponding to the scope 0, in which all flash memory cells 16 composing the used area 25 are in the erased state. Similarly, the queues 2 and 3 are assigned for the scope 1 of the address translation table 27 to store the physical block addresses of the blocks, which belong to the area corresponding to the scope 1, in which all flash memory cells 16 composing the used area 25 are in the erased state, the queues 4 and 5 are assigned for the scope 2 of the address translation table 27 to store the physical block addresses of the blocks, which belong to the area corresponding to the scope 2, in which all flash memory cells 16 composing the used area 25 are in the erased state, and the queues 6 and 7 are assigned for the scope 3 of the address translation table 27 to store the physical block addresses of the blocks, which belong to the area corresponding to the scope 3, in which all flash memory cells 16 composing the used area 25 are in the erased state.

The generation of the erased block queue 30 is performed under the control of the microprocessor 6 during the generation of the address translation table 27.

Specifically, as mentioned above, the erase flag indicating whether or not the corresponding block is an erased block is included in the redundant area 26 of the top page (page 0) of each of the blocks, and the contents of the erase flags, which are included in the area whose address translating information should be stored in the address translation table 27, are checked to detect erased blocks under the control of the microprocessor 6 during the generation of the address translation table 27. By this operation, at most two erased blocks are detected per each of the 4 areas whose address translating information should be stored in the address translation table 27 and the physical block addresses thereof are stored in the corresponding queues.

Next, the initializing operation, read operation, and write operation of the flash memory system 1 will be explained in this order.

The initialization of the flash memory system 1 is performed at the time the flash memory system 1 is attached to the host computer 5 or a reset command is issued from the host computer 5.

In the initialization of the flash memory system 1, at first, address translating information of the top 4 areas, i.e., areas 0 to 3, among the 32 areas of the flash memory chips 2-0 to 2-3, is read out and stored in the scopes 0 to 3 of the address translation table 27, respectively. Storage of address translating information in the address translation table 27 was explained earlier.

Further, the management table 28 is generated under the control of the microprocessor 6.

As explained above, the management table 28 is a table indicating which address translating information is stored in the scopes 0 to 3 of the address translation table 27. In the initial state, because address translating information of areas 0 to 3 is stored in the scopes 0 to 3, respectively, the area numbers “0” to “3” are stored in the area number storing areas 0 to 3 of the management table 28, respectively.

Further, the priority link 29 is generated under the control of the microprocessor 6.

As mentioned above, the priority link 29 is an element for indicating the priority order of the scopes 0 to 3 based on the access history. In the initial state, because no access has been performed for any area, it is impossible to determine the priority order based on access history. Therefore, in the initialization of the flash memory system 1, the linked pointer numbers and data “NULL” as shown in FIG. 9 are provisionally stored in the pointers 0 to 3 of the priority link 29 under the control of the microprocessor 6. Thus, the priority order indicated-by the priority link 29 becomes scope 0→scope 1→scope 2→scope 3 when the initialization is completed.

Further, the erased block queue 30 is generated under the control of the microprocessor 6.

As explained above, the erased block queue 30 is an element for storing the physical block addresses of the erased blocks which belong to the areas corresponding to the scopes 0 to 3. Generation of the erased block queue 30 was explained earlier.

When the address translation table 27, management table 28, priority link 29, and erased block queue 30 have been generated by the completion of above-mentioned operations, the initialization of the flash memory system 1 is finished.

The controller 3 is placed in a busy state during the initialization of the flash memory system 1. When in the state the controller 3 denies requests for data reading or writing from the host computer 5. The busy state is released in response to completion of flash memory system 1 initialization.

Next, the read operation of the flash memory system 1 will be explained.

The read operation of the flash memory system 1 will be explained separately for the case where address translating information of the area assigned to the host address supplied from the host computer 5 is and is not stored in the address translation table 27.

First, the read operation of the flash memory system 1 will be explained for the case where address translating information of the area assigned to the host address supplied from the host computer 5 is stored in the address translation table 27.

In the case that the address translation table 27, management table 28, priority link 29, and erased block queue 30 are in the initial state, when the external read command and the host address are supplied to the flash memory system 1 via the bus 14, the connector 4, and the bus 13 from the host computer 5, the external read command and the host address are input to the controller 3 via the host interface block 7. Here, assume that the host address is 0000100000000110011B.

When the external read command and the host address are supplied to the controller 3, registers (not shown) included in the flash sequencer block 12 are set under the control of the microprocessor 6 to transfer user data from the flash memory chips 2-0 to 2-3 to the buffer 9. This operation is performed as follows:

First, an internal read command, a kind of internal command, is set in predetermined registers (not shown) included in the flash sequencer block 12 under the control of the microprocessor 6.

Further, the upper 2 bits are extracted from the 20 bits of the host address and set in other registers (not shown) included in the flash sequencer block 12 under the control of the microprocessor 6.

Further, the upper 5 bits are extracted from the 20 bits of the host address and the area number storing areas are searched to select from among the area number storing areas 0 to 3 of the management table 28 the one which stores the area number matching the extracted 5 bits. In the exemplified case, because the upper 5 bits of the host address are 00001B(1), the area number storing area 1 in which 00001B(1) is stored as the area number is selected. Thus, it can be detected that address translating information corresponding to the given host address is stored in the scope 1 of the address translation table 27.

Further, the 10 bits composed of the upper 6 bit to 15 bit are extracted from the 20 bits of the host address and the physical block address, which is stored in the physical block address storing area determined by the extracted 10 bits among the 1024 physical block address storing areas composed of the physical block address storing area 1024 to 2047 included in the scope 1 of the address translation table 27, is read out under the control of the microprocessor 6. In the exemplified case, because the extracted 10 bits of the host address are 0000000011B(3), the physical block address stored in the fourth (3+1) physical block address storing area, which is the physical block address storing area 1027, is read out. Here, assume that the physical block address stored in the physical block address storing area 1027 is 0101010101B(341).

Next, the 10 bits composed of the upper 6 bit to 15 bit of the host address are replaced with the physical block address read from the address translation table 27 and upper 2 bits are removed to generate an internal address of 18 bits under the control of the microprocessor 6. In this case, because the physical block address read from the address translation table 27 is 0101010101B, the internal address of 18 bits becomes 001010101010100111B.

Then, the internal address generated by such operations is set in other registers (not shown) included in the flash sequencer block 12 under the control of the microprocessor 6.

When the setting of the various registers (not shown) of the flash sequencer block 12 is completed by the above-mentioned various operations, the sequential read operation by the flash sequencer block 12 is started. The sequential read operation by the flash sequencer block 12 is performed as follows:

First, the flash sequencer block 12 directs the flash memory interface block 10 to activate the one of the chip selection signals #0 to #3 corresponding to the flash memory chip to be accessed among the flash memory chips 2-0 to 2-3 based on the upper 2 bits of the host address stored in the registers (not shown) thereof. In the exemplified case, because the upper 2 bits of the host address are 00B(0), the chip selection signal #0 is activated. Therefore, access of the flash memory chip 2-0 is enabled. The other chip selection signals #1 to #3 are kept in the inactive state.

Next, the flash sequencer block 12 directs the flash memory interface block 10 to send the internal address of 18 bits, which is 001010101010100111B, and the internal read command, stored in the prescribed register (not shown), to the bus 15. Although the internal address of 18 bits and the internal read command are provided in common for the flash memory chips 2-0 to 2-3 via the bus 15, they are only valid for the flash memory chip 2-0 because the chip selection signal #0 is in the active state while the other the chip selection signals #1 to #3 are in the inactive state.

As a result, the flash memory chip 2-0 can read data stored at the given internal address of 18 bits, 001010101010100111B. The upper 13 bits of the given internal address of 18 bits are used to select the block to be accessed and the lower 5 bits of the given internal address of 18 bits are used to select the page to be accessed included in the selected block. In the exemplified case, because the upper 13 bits of the given internal address are 0010101010101B and the lower 5 bits of the given internal address are 00111B, the block 1365 and the page 7 are selected. That is, the flash memory chip 2-0 reads data stored at page 7 of the block 1365. Not only user data stored in the user area 25 but also additional information stored in the redundant area 26 are read out during such a read operation.

By the above operations, the user data and additional information read from the flash memory chip 2-0 are supplied to the flash memory interface block 10 via the bus 15. When the flash memory interface block 10 receives the user data and additional information, the error correction code included in the additional information is extracted and the user data and the error correction code are supplied to the ECC block 11 under the control of the flash sequencer block 12. When the error correction code is supplied to the ECC block 11, the ECC block 11 judges based on the error correction code whether or not the user data includes any error. As a result, if the ECC block 11 judges that the user data does not include any error, the ECC block 11 supplies the user data unmodified to the buffer 9. If the ECC block 11 judges that the user data includes an error, the ECC block 11 corrects the user data based on the error correction code and supplies the corrected user data to the buffer 9. Then the error-free user data are temporarily stored in the buffer 9, whereby the sequential read operation by the flash sequencer block 12 is completed.

Then, the user data stored in the buffer 9 are transferred to the host computer 5 via the host interface block 7, the bus 13, the connector 4, and the bus 14 under the control of the microprocessor 6.

Further, the microprocessor 6 updates the content of the priority link 29 in response to the above-mentioned read operation. Specifically, the contents of the pointers 0 to 3 of the priority link 29 are now “1”, “2”, “3”, and “NULL”, respectively, to indicate the priority order as scope 0→scope 1→scope 2→scope 3. In response to the area corresponding to the scope 1 being accessed, the content of the pointer 0, whose stored linked pointer number is the same number as the scope number of the now-accessed scope (scope 1), is overwritten to the content (2) of the pointer (pointer 1), which corresponds to the now-accessed scope (scope 1). Further, the content of the pointer (pointer 1), which corresponds to the now-accessed scope (scope 1), is overwritten to the number (0) of the most significant scope (scope 0). By these operations, the contents of the pointers 0 to 3 of the priority link 29 become “2”, “0”, “3”, and “NULL”, respectively, so that the priority order becomes scope 1→scope 0→scope 2→scope 3.

This completes the read operation.

Next, the read operation of the flash memory system 1 will be explained in the case that address translating information of the area assigned to the host address supplied from the host computer 5 is not stored in the address translation table 27.

Assume that the contents of the address translation table 27, the management table 28, the priority link 29, and the erased block queue 30, each of which is stored in the SRAM work area 8, are the contents at the time when the above-mentioned read operation is completed. Also assume that the host address given with the external read command is 11111000001111101010B which selects a block whose address translating information is not stored in the address translation table 27.

When the external read command and the host address are supplied to the controller 3, registers (not shown) included in the flash sequencer block 12 are set under the control of the microprocessor 6 to transfer user data from the flash memory chips 2-0 to 2-3 to the buffer 9. This operation is performed as follows:

First, the internal read command is set in the predetermined registers (not shown) included in the flash sequencer block 12 under the control of the microprocessor 6.

Further, the upper 2 bits are extracted from the 20 bits of the host address and set in other registers (not shown) included in the flash sequencer block 12 under the control of the microprocessor 6.

Further, the upper 5 bits are extracted from the 20 bits of the host address and the area number storing areas are searched to select from among the area number storing areas 0 to 3 of the management table 28 the one which stores the area number matching the extracted 5 bits. In the exemplified case, because the upper 5 bits of the host address are 11111B(32), no area number storing area can be selected.

This means that address translating information of the area 31 to be accessed is not stored in the address translation table 27. Therefore, address translating information of the area 31 must be stored in the address translation table 27 to access the area 31. This operation is performed as follows:

First, the pointer in which data “NULL” is stored is searched from among the pointers 0 to 3 of the priority link 29. In the exemplified case, the pointer in which data “NULL” is stored is the pointer 3, as mentioned above. Because the scope whose corresponding pointer stores the data “NULL” is the least significant, it can be detected that the priority of the scope 3 is the least significant.

In response to the priority of the scope 3 being the least significant, all the contents stored in the physical block address storing areas 3072 to 4095 composing the scope 3 are erased, and address translating information of the area 31 to be accessed is stored in the scope 3. After the address translating information of the area 31 is stored in the scope 3, the area number storing area 3 of the management table 28 is updated to “31”. Thus, the relationship between the area 31 and the scope 3 is established.

After the updating of the address translation table 27 and the management table 28 is completed, the 10 bits composed of the upper 6 bit to 15 bit are extracted from the 20 bits of the host address and the physical block address, which is stored in the physical block address storing area determined by the extracted 10 bits among the 1024 physical block address storing areas composed of the physical block address storing area 3072 to 4095 included in the scope 3 of the address translation table 27, is read out under the control of the microprocessor 6. In the exemplified case, because the extracted 10 bits of the host address are 0000011111B(31), the physical block address stored in the thirty-second (31+1) physical block address storing area, which is the physical block address storing area 4103, is read out. Here, assume that the physical block address stored in the physical block address storing area 4103 is 1111100000B(992).

Next, the 10 bits composed of the upper 6 bit to 15 bit of the host address are replaced with the physical block address read from the address translation table 27 and the upper 2 bits are removed to generate the internal address of 18 bits under the control of the microprocessor 6. In the exemplified case, because the physical block address read from the address translation table 27 is 1111100000B, the internal address of 18 bits becomes 111111110000001010B.

Then, the internal address generated by such operations is set in other registers (not shown) included in the flash sequencer block 12 under the control of the microprocessor 6.

When the setting of the various registers (not shown) of the flash sequencer block 12 is completed by the above-mentioned various operations, the sequential read operation by the flash sequencer block 12 is started. The sequential read operation by the flash sequencer block 12 is performed as follows:

First, the flash sequencer block 12 directs the flash memory interface block 10 to activate the one of the chip selection signals #0 to #3 corresponding to the flash memory chip to be accessed among the flash memory chips 2-0 to 2-3 based on the upper 2 bits of the host address stored in the registers (not shown) thereof. In the exemplified case, because the upper 2 bits of the host address are 11B(3), the chip selection signal #3 is activated. Therefore, access of the flash memory chip 2-3 is enabled. The other chip selection signals #0 to #2 are kept in the inactive state.

Next, the flash sequencer block 12 directs the flash memory interface block 10 to send the internal address of 18 bits, which is 111111110000001010B, and the internal read command stored in the prescribed register (not shown) to the bus 15. Although the internal address of 18 bits and the internal read command are provided in common for the flash memory chips 2-0 to 2-3 via the bus 15, they are only valid for the flash memory chip 2-3 because the chip selection signal #3 is in the active state while the other the chip selection signals #0 to #2 are in the inactive state.

As a result, the flash memory chip 2-3 can read data stored at the given internal address of 18 bits, 111111110000001010B. The upper 13 bits of the given internal address of 18 bits are used to select the block to be accessed and the lower 5 bits of the given internal address of 18 bits are used to select the page to be accessed included in the selected block. In the exemplified case, because the upper 13 bits of the given internal address are 1111111100000B and the lower 5 bits of the given internal address are 01010B, the block 32736 (8159th block in the flash memory chip 2-3) and the page 10 are selected. That is, the flash memory chip 2-3 reads data stored at page 10 of the block 32736. Not only user data stored in the user area 25 but also additional information stored in the redundant area 26 are read out during such a read operation.

By the above operations, the user data and additional information read from the flash memory chip 2-3 are supplied to the flash memory interface block 10 via the bus 15. When the flash memory interface block 10 receives the user data and additional information, the error correction code included in the additional information is extracted and the user data and the error correction code are supplied to the ECC block 11 under the control of the flash sequencer block 12. When the error correction code is supplied to the ECC block 11, the ECC block 11 judges based on the error correction code whether or not the user data includes any error. As a result, if the ECC block 11 judges that user data does not include an error, the ECC block 11 supplies the user data unmodified to the buffer 9. If the ECC block 11 judges that user data includes an error, the ECC block 11 corrects the user data based on the error correction code and supplies the corrected user data to the buffer 9. Then error-free user data are temporarily stored in the buffer 9, whereby the sequential read operation by the flash sequencer block 12 is completed.

Then, the user data stored in the buffer 9 are transferred to the host computer 5 via the host interface block 7, the bus 13, the connector 4, and the bus 14 under the control of the microprocessor 6.

Further, the microprocessor 6 updates the content of the priority link 29 in response to the above-mentioned read operation. Specifically, the contents of the pointers 0 to 3 of the priority link 29 are now “2”, “0”, “3”, and “NULL”, respectively, to indicate the priority order as scope 1→scope 0→scope 2→scope 3. In response to the area corresponding to the scope 3 being accessed, the content of the pointer 2, whose stored linked pointer number is the same number as the scope number of the now-accessed scope (scope 3), is overwritten to the content (NULL) of the pointer (pointer 3), which corresponds to the now-accessed scope (scope 3). Further, the content of the pointer (pointer 3), which corresponds to the now-accessed scope (scope 3), is overwritten to the number (1) of the most significant scope (scope 1). By these operations, the contents of the pointers 0 to 3 of the priority link 29 become “2”, “0”, “NULL”, and “1”, respectively, so that the priority order becomes scope 3→scope 1→scope 0→scope 2.

This completes the read operation.

Next, the data write operation of the flash memory system 1 will be explained.

The write operation of the flash memory system 1 will be explained separately for the case of a new data write operation for writing new data into a block having no data stored therein and the case of a data overwrite operation for overwriting data into a block already storing data therein.

The new data write operation of the flash memory system 1 will be explained first.

Assume that the contents of the address translation table 27, the management table 28, the priority link 29, and the erased block queue 30, each of which is stored in the SRAM work area 8, are the contents at the time when the above-mentioned two read operations are completed. Also assume that the host address given with the external write command and user data to be written is 00000111111111100000B, which selects a block having no data are not stored therein. When the external write command, the host address, and user data to be written are supplied to the flash memory system 1 from the host computer 5 via the bus 14, the connector 4, and the bus 13, they are input into the controller 3.

First, user data to be written are transferred to the ECC block 11 when the external write command, the host address, and the user data to be written are supplied to the controller 3. In response to receipt of the user data, the ECC block 11 analyzes the user data to generate the error correction code and the ECC block 11 temporarily stores it. On the other hand, the user data are stored in the buffer 9.

Next, the registers (not shown) included in the flash sequencer block 12 are set under the control of the microprocessor 6 to write the user data, which are temporarily stored in the buffer 9, into the page among the flash memory chips 2-0 to 2-3 which is selected by the given host address. This operation is performed as follows:

First, the internal write command, which is a kind of internal command, is set in the predetermined registers (not shown) included in the flash sequencer block 12 under the control of the microprocessor 6.

Further, the upper 2 bits are extracted from the 20 bits of the host address and set in the other registers (not shown) included in the flash sequencer block 12 under the control of the microprocessor 6.

Further, the upper 5 bits are extracted from the 20 bits of the host address and the area number storing area is searched to select from among the area number storing areas 0 to 3 of the management table 28 the area number storing is the same number as the extracted 5 bits. In the exemplified case, because the upper 5 bits of the given host address are 00000B(0), the area number storing area 0 in which “00000B(0)” is stored as the area number is selected. Thus, it can be detected that address translating information corresponding to the given host address is stored in the scope 0 of the address translation table 27.

Further, the 10 bits composed of the upper 6 bit to 15 bit are extracted from the 20 bits of the host address and the physical block address, which is stored in the physical block address storing area determined by the extracted 10 bits among the 1024 physical block address storing areas composed of the physical block address storing area 0 to 1023 included in the scope 0 of the address translation table 27, is read out under the control of the microprocessor 6. In the exemplified case, because the extracted 10 bits of the host address are 1111111111B(1023), the physical block address stored in the 1024th (1023+1) physical block address storing area, which is the physical block address storing area 1023, is read out. As mentioned above, because this is a new data write operation to write new data into a block not stored any data, no physical block address is stored in the physical block address storing area 1023,

Next, the physical block address stored in the queue 0 assigned to the scope 0 of the address translation table 27 among the queues 0 to 7 of the erased block queue 30 is read out under the control of the microprocessor 6. Assume that the physical block address stored in the queue 0 is 0000000100B(4). As mentioned above, the physical block address stored in the queue 0 of the erased block queue 30 is the physical block address of the erased block.

The read physical block address “0000000100B(4)” from the queue 0 is stored in the physical block address storing area 1023 of the scope 0 of the address translation table 27 under the control of the microprocessor 6. Further, the 10 bits composed of the upper 6 bit to 15 bit of the host address are replaced with the physical block address read from the queue 0 and upper 2 bits are removed to generate the internal address of 18 bits under the control of the microprocessor 6. In the exemplified case, because the physical block address read from the queue 0 is 0000000100B, the internal address of 18 bits becomes 000000000010000000B.

Then, the internal address generated by such operations is set in other registers (not shown) included in the flash sequencer block 12 under the control of the microprocessor 6.

When the setting of the various registers (not shown) of the flash sequencer block 12 is completed by the above-mentioned various operations, the sequential write operation by the flash sequencer block 12 is started. The sequential write operation by the flash sequencer block 12 is performed as follows:

At first, the flash sequencer block 12 directs the flash memory interface block 10 to activate the one of the chip selection signals #0 to #3 corresponding to the flash memory chip to be accessed among the flash memory chips 2-0 to 2-3 based on the upper 2 bits of the host address stored in the registers (not shown) thereof. In the exemplified case, because the upper 2 bits of the host address are 00B(0), the chip selection signal #0 is activated. Therefore, access of the flash memory chip 2-0 is enabled. The other chip selection signals #1 to #3 are kept in the inactive state.

Next, the flash sequencer block 12 directs the flash memory interface block 10 to send the internal address of 18 bits, which is 000000000010000000B, and the internal write command stored in the prescribed registers (not shown) to the bus 15. Although the internal address of 18 bits and the internal write command are provided in common for the flash memory chips 2-0 to 2-3 via the bus 15, they are only valid for the flash memory chip 2-0 because the chip selection signal #0 is in the active state while the other the chip selection signals #1 to #3 are in the inactive state.

As a result, the flash memory chip 2-0 is enabled to write user data into the given internal address of 18 bits, 000000000010000000B. The upper 13 bits of the given internal address of 18 bits are used to select the block to be accessed and the lower 5 bits of the given internal address of 18 bits are used to select the page to be accessed included in the selected block. In the exemplified case, the page 0 of the block 4 is selected.

Next, the user data to be written temporarily stored in the buffer 9 is supplied to the bus 15 via the flash memory interface block 10 under the control of the flash sequencer block 12. Although user data supplied to the bus 15 is supplied in common to the flash memory chips 2-0 to 2-3, it is only valid for the flash memory chip 2-0 because only the chip selection signal #0 is in the active state.

Then, the user data are written into the user area 25 of page 0 of the block 4 of the flash memory chip 2-0 because the flash memory chip 2-0 is enabled to write user data thereto. Further, the error correction code temporarily stored in the ECC block 11 is supplied to the bus 15 via the flash memory interface block 10. Then, the error correction code is written into the redundant area 26 of page 0 of the block 4 of the flash memory chip 2-0 because the flash memory chip 2-0 is enabled to write the error correction code thereto. This completes the sequential write operation by the flash sequencer block 12.

Further, the microprocessor 6 updates the content of the priority link 29 in response to the above-mentioned write operation. Specifically, the contents of the pointers 0 to 3 of the priority link 29 are now “2”, “0”, “NULL”, and “1”, respectively, to indicate the priority order as scope 3→scope 1→scope 0→scope 2. In response to the area corresponding to the scope 0 being accessed, the content of the pointer 1, whose stored linked pointer number is the same number as the scope number of the now-accessed scope (scope 0), is overwritten to the content (2) of the pointer (pointer 0), which corresponds to the now-accessed scope (scope 0). Further, the content of the pointer (pointer 0), which corresponds to the now-accessed scope (scope 0), is overwritten to the number (3) of the most significant scope (scope 3). By these operations, the contents of the pointers 0 to 3 of the priority link 29 become “3”, “2”, “NULL”, and “1”, respectively, so that the priority order becomes scope 0→scope 3→scope 1→scope 2.

Further, the microprocessor 6 searches the erased block from the area 0, which corresponds to the scope 0, to overwrite the content of the queue 0 of the erased block queue 30, because the content thereof is not the physical block address of the erased block anymore.

This completes the write operation.

Next, the data overwrite operation of the flash memory system 1 will be explained.

In the data overwrite operation, it is required to transfer data stored in the block including the page to be overwritten to another block. The reason for this was explained earlier.

Here, assuming that the contents of the address translation table 27, the management table 28, the priority link 29, and the erased block queue 30, each of which is stored in the SRAM work area 8, are the contents at the time when the above mentioned two read operations and the one write operation are completed. Also assume that the host address given with the external write command and user data to be written is 11000000100100111011B, which selects a block already storing data. When the external write command, the host address, and the user data to be written are supplied to the flash memory system 1 from the host computer 5 via the bus 14, the connector 4, and the bus 13, the controller 3 receives them at first.

First, the user data to be written are transferred to the ECC block 11 when the external write command, the host address, and the user data to be written are supplied to the controller 3. In response to receipt of the user data, the ECC block 11 analyzes the user data to generate the error correction code and the ECC block 11 temporarily stores it. On the other hand, the user data are stored in the buffer 9.

Next, the registers (not shown) included in the flash sequencer block 12 are set under the control of the microprocessor 6 to write the user data, which is temporarily stored in the buffer 9, into the specific page among the flash memory chips 2-0 to 2-3 which is selected by the given host address. This operation is performed as follows:

First, the internal write command and the internal read command are set in the predetermined registers (not shown) included in the flash sequencer block 12 under the control of the microprocessor 6.

Further, the upper 2 bits are extracted from the 20 bits of the host address and set in other registers (not shown) included in the flash sequencer block 12 under the control of the microprocessor 6.

Further, the source block address which is the physical block address of the block storing the data prior to transfer, and the destination block address which is the physical block address of the block in which transferred data will be stored, are set in other registers (not shown) included in the flash sequencer block 12 under the control of the microprocessor 6.

In accordance with the generation of the source block address, the upper 5 bits are extracted from the 20 bits of the host address and the area number storing areas are searched to select from among the area number storing areas 0 to 3 of the management table 28 the one which stores the area number matching the extracted 5 bits. In the exemplified case, because the upper 5 bits of the given host address are 11000B(24), no area number storing area can be selected.

This means that address translating information of the area 24 to be accessed is not stored in the address translation table 27. Therefore, address translating information of the area 24 must be stored in the address translation table 27 to access the area 24. This operation is performed as follows:

First, the pointer in which data “NULL” is stored is searched from among the pointers 0 to 3 of the priority link 29. In the exemplified case, the pointer in which data “NULL” is stored is the pointer 2, as mentioned above. Because the scope whose corresponding pointer stores the data “NULL” is the least significant, it can be detected that the priority of the scope 2 is the least significant.

In response to the priority of the scope 2 being the least significant, all the contents stored in the physical block address storing areas 2048 to 3071 composing the scope 2 are erased, and address translating information of the area 24 to be accessed is stored in the scope 2. After the address translating information of the area 24 is stored in the scope 2, the area number storing area 2 of the management table 28 is updated to “24”. Thus, the relationship between the area 24 and the scope 2 is established. Further, the contents of the queues 4 and 5 assigned to the scope 2 among the queues 0 to 7 of the erased block queue 30 are erased, the erased blocks are searched from the area 24 which corresponds to the scope 2, and the physical block addresses thereof are overwritten into the queues 4 and 5 of the erased block queue 30.

After above updating of the address translation table 27, the management table 28, and the erased block queue 30 is completed, the 10 bits composed of the upper 6 bit to 15 bit are extracted from the 20 bits of the host address, and then, the physical block address, which is stored in the physical block address storing area determined by the extracted 10 bits among the 1024 physical block address storing areas composed of the physical block address storing area 2048 to 3071 included in the scope 2 of the address translation table 27, is read out under the control of the microprocessor 6. In the exemplified case, because the extracted 10 bits of the host address are 0001001001B(73), the physical block address stored in the seventy-fourth (73+1) physical block address storing area, which is the physical block address storing area 2121, is read out. Here, assume that the physical block address stored in the physical block address storing area 2121 is 1110001111B(911). This is the source block address, and it is set in a register (not shown) included in the flash sequencer block 12.

On the other hand, in accordance with the generation of the destination block address, the physical block address stored in the queue 4 assigned to the scope 2 of the address translation table 27 among the queues 0 to 7 of the erased block queue 30 is read out under the control of the microprocessor 6. Assume that the physical block address stored in the queue 4 is 1000000000B(512). This is the destination block address, and it is set in a register (not shown) included in the flash sequencer block 12.

When the setting of the various registers (not shown) of the flash sequencer block 12 is completed by the above-mentioned operations, the sequential write operation by the flash sequencer block 12 is started. The sequential write operation by the flash sequencer block 12 is performed as follows:

First, the flash sequencer block 12 directs the flash memory interface block 10 to activate the one of the chip selection signals #0 to #3 corresponding to the flash memory chip to be accessed among the flash memory chips 2-0 to 2-3 based on the upper 2 bits of the host address stored in the registers (not shown) thereof, In the exemplified case, because the upper 2 bits of the host address is 11B(3), the chip selection signal #3 is activated. Therefore, access of the flash memory chip 2-3 is enabled. The other chip selection signals #0 to #2 are kept in the inactive state.

Next, the flash sequencer block 12 generates the internal source address of 18 bits by joining the 3 bits composing from the upper 3 bit to the upper 5 bit, the source block address stored in the certain register (not shown) of the flash sequencer block 12, and 00000B. That is, the internal source address is 000111000111100000B.

Next, the flash sequencer block 12 directs the flash memory interface block 10 to send the internal source address of 18 bits, which is 000111000111100000B, and the internal read command stored in the prescribed registers (not shown) to the bus 15. Although the internal address of 18 bits and the internal read command are provided in common to the flash memory chips 2-0 to 2-3 via the bus 15, they are only valid for the flash memory chip 2-3 because the chip selection signal #3 is in the active state while the other the chip selection signals #0 to #2 are in the inactive state.

As a result, the flash memory chip 2-3 can read data stored at the given internal source address of 18 bits, 000111000111100000B. The upper 13 bits of the given internal source address of 18 bits is used to select the block to be accessed and the lower 5 bits of the given internal source address of 18 bits are used to select the page to be accessed included in the selected block. In the exemplified case, because the upper 13 bits of the given internal address are 0001110001111B and the lower 5 bits of the given internal address are 00000B, the block 25487 and the page 0 are selected. That is, the flash memory chip 2-3 reads data stored at the page 0 of the block 25487.

By the above operations, the user data read from the flash memory chip 2-3 is supplied to the flash memory interface block 10 via the bus 15. When the flash memory interface block 10 receives the user data, the user data are transferred to the buffer 9 and the ECC block 11 to temporarily store them in the buffer 9 and to generate the error correction code. The error correction code is temporarily stored in the ECC block 11.

Next, the write operation of the data temporarily stored in the buffer 9 is performed.

Specifically, the flash sequencer block 12 generates the internal destination address of 18 bits by joining the 3 bits composed of the upper 3 bit to the upper 5 bit, the destination block address stored in the certain register (not shown) of the flash sequencer block 12, and 00000B. That is, the internal source address is 000100000000000000B.

Next, the flash sequencer block 12 directs the flash memory interface block 10 to send the internal destination address of 18 bits, which is 000100000000000000B, and the internal write command stored in the prescribed registers (not shown) to the bus 15. Although the internal address of 18 bits and the internal read command are provided in common to the flash memory chips 2-0 to 2-3 via the bus 15, they are only valid for the flash memory chip 2-3 because the chip selection signal #3 is in the active state while the other the chip selection signals #0 to #2 are in the inactive state.

As a result, the flash memory chip 2-3 is enabled to write the user data at the given internal address of 18 bits, 000100000000000000B. Because the upper 13 bits of the given internal address of 18 bits are used to select the block to be accessed, and the lower 5 bits of the given internal address of 18 bits are used to select the page to be accessed included in the selected block, the page 0 of the block 25088 is selected.

Next, the user data to be written temporarily stored in the buffer 9 are supplied to the bus 15 via the flash memory interface block 10 under the control of the flash sequencer block 12. Although the user data supplied to the bus 15 is supplied in common to the flash memory chips 2-0 to 2-3, it is only valid for the flash memory chip 2-3 because only the chip selection signal #3 is in the active state.

Then, the user data are written into the user area 25 of page 0 of the block 25088 of the flash memory chip 2-3 because the flash memory chip 2-3 is enabled to perform to write user data thereto. Further, the error correction code temporarily stored in the ECC block 11 is supplied to the bus 15 via the flash memory interface block 10. Then, the error correction code is written into the redundant area 26 of page 0 of the block 25088 of the flash memory chip 2-3 because the flash memory chip 2-3 is enabled to perform to write the error correction code thereto. This completes the transfer of data from the page 0 of the block 25487 to the page 0 of the block 25088.

Next, the internal source address is incremented to generate the new internal source address 000111000111100001B. Then, data stored in the page (page 1) selected by the new internal source address 000111000111100001B is read out for temporary storage in the buffer 9 by the above-mentioned operations.

Further, the internal destination address is incremented to generate the new internal destination address 000100000000000001B. Then, the data temporarily stored in the buffer 9 is written into the page (page 1) selected by the new internal destination address 000100000000000001B by above-mentioned operations. This completes the transfer of data from the page 1 of the block 25487 to the page 1 of the block 25088.

Such data transferring operations are successively performed until the lower 5 bits of the internal source address are the same as the lower 5 bits of the host address, which is 11011B(27). Specifically, when the lower 5 bits of the internal source address become the same as the lower 5 bits of the host address 11011B(27) during the above-mentioned increment operation, the read operation for the block 25088 using the internal source address is temporarily suspended. Then, the flash sequencer block 12 increments the internal destination to generate the new internal destination address 000100000000011011B and performs the write operation to write user data, which is supplied from the host computer 5 and stored in the buffer 9, into the page selected by the new internal destination address 000100000000011011B.

When the write operation of the user data supplied from the host computer 5 is completed, the internal source address is incremented to generate the new internal source address 000111000111111100B. Then, the read operation for the block 25088 using the internal source address is restarted so that data stored in the page (page 28) selected by the new internal source address 000111000111111100B is read out for temporary storage in the buffer 9.

Similarly, the internal destination address is also incremented to generate the new internal destination address 000100000000011100B. Then, the data temporarily stored in the buffer 9 is written into the page (page 28) selected by the new internal destination address 000100000000011100B by the above-mentioned operations. This completes the transfer of data from the page 28 of the block 25487 to the page 28 of the block 25088.

Such data transferring operations are successively performed until data transfer from the final page (page 31) of the block 25487 to the final page (page 31) of the block 25088 is completed. That is, when data transfer from the final page (page 31) of the block 25487 to the final page (page 31) of the block 25088 is completed, the sequential write operation under the control of the flash sequencer block 12 is completed.

Further, the microprocessor 6 updates the content of the priority link 29 in response to the above-mentioned write operation. Specifically, the contents of the pointers 0 to 3 of the priority link 29 are now “3”, “2”, “NULL”, and “1”, respectively, to indicate the priority order as scope 0→scope 3→scope 1→scope 2. In response to the area corresponding to the scope 2 being accessed, the content of the pointer 1, whose stored linked pointer number stored is the same number as the scope number of the now-accessed scope (scope 2), is overwritten to the content (NULL) of the pointer (pointer 2), which corresponds to the now-accessed scope (scope 2). Further, the content of the pointer (pointer 2), which corresponds to the now-accessed scope (scope 2), is overwritten to the number (0) of the most significant scope (scope 0). By these operations, the contents of the pointers 0 to 3 of the priority link 29 become “3”, “NULL”, “0”, and “1”, respectively, so that the priority order becomes scope 2→scope 0→scope 3→scope 1.

Further, the microprocessor 6 searches the erased block from the area 24, which corresponds to the scope 2, to overwrite the content of the queue 4 of the erased block queue 30 because the content thereof is not the physical block address of the erased block anymore.

This completes the write operation.

In the flash memory system 1 according to above described embodiment of the present invention, the memory capacity required for the address translation table 27 can be reduced because the address space of the flash memory chips 2-0 to 2-3 is divided into 32 areas composing the areas 0 to 31 and not all address translating information for the areas 0 to 31 but only 4 pieces of address translating information are stored in the address translation table 27 composed of the scopes 0 to 3.

The present invention can be embodied as a PC card conforming with the standard regulation proposed by the PCMCIA (Personal Computer Memory Card International Association). Further, the present invention can be embodied as a highly miniaturized memory card realized by the development of high-integration technologies for semiconductor devices, such as the Compact Flash™ proposed by the CFA (Compact Flash Association), the SmartMedia# proposed by the SSFDC Forum, the MMC™ (MultiMedia Card) proposed by the MultiMedia Card Association, the Memory Stick™ proposed by SONY corporation, or the like.

The present invention has thus been shown and described with reference to specific embodiments. However, it should be noted that the present invention is in no way limited to the details of the described arrangements but changes and modifications may be made without departing from the scope of the appended claims.

For example, in the flash memory system 1 according to the above described embodiment, the flash memory system 1 is embodied as a card. However, the flash memory system according to the present invention is not limited to a card-shape and can be embodied in other shapes such as stick-shaped.

Further, in the flash memory system 1 according to the above described embodiment, the flash memory system 1 is embodied as a card in which the 4 flash memory chips 2-0 to 2-3 and the controller 3 being integrated. However, the present invention is not limited to the flash memory chips 2-0 to 2-3 and the controller 3 are integrated in the same package, they can be packed in individual packages. In this case, connectors must be added the package for the flash memory chips 2-0 to 2-3 and the package for the controller 3 to establish electrical and physical connection therebetween. Therefore, the package for the flash memory chips 2-0 to 2-3 can be removably attached to the package for the controller 3. Moreover, the invention is also not limited to the flash memory chips 2-0 to 2-3 being integrated in the same package but also encompasses the case where they are packed in individual packages.

Furthermore, in the flash memory system 1 according to the above described embodiment, 4 flash memory chips 2-0 to 2-3 are employed in the flash memory system 1 controlled by the controller 3. However, the present invention is not limited to the number of the flash memory chips employed in the flash memory system and controlled by the controller being 4. That is, it is possible for the number of the flash memory chips employed in the flash memory system and controlled by the controller to be another number such as 1 or 8.

Further, in the flash memory system 1 according to the above described embodiment, the memory capacity of each of the flash memory chips 2-0 to 2-3 is 128M bytes (1G bits). However, the memory capacity of each of the flash memory chips employed in the flash memory system according to the present invention is not limited to 128M bytes (1G bits) and can be another capacity such as 32M bytes (256M bits).

Furthermore, in the flash memory system 1 according to the above described embodiment, each page constituting the minimum access unit is composed of 512 bytes. However, the capacity of the page constituting the minimum access unit is not limited to 512 bytes but can be another capacity.

Further, in the flash memory system 1 according to the above described embodiment, these 4 flash memory chips 2-0 to 2-3 are treated as a big single memory having 1M pages of address space. However, each flash memory chips 2-0 to 2-3 can be treated as an individual memory.

Furthermore, in the flash memory system 1 according to the above described embodiment, each flash memory cell 16 employed in the flash memory chips 2-0 to 2-3 can store 1 bit of data. However, the flash memory cells employed in the flash memory chip can be ones enabled to store 2 or more bits of data by controlling the number of electrons injected into the floating gate electrode 21.

Further, in the flash memory system 1 according to the above described embodiment, each of the address space of the flash memory chips 2-0 to 2-3 is divided into 8 areas. However, the number of the divided areas of each of the flash memory chips 2-0 to 2-3 is not limited to 8 and can be another number such as 4 or 16. As the number of the divided areas of each of the flash memory chips 2-0 to 2-3 decreases, the access speed increase because the frequency of updating of the address translation table 27 becomes low while the capacity required for the address translation table 27 increases because the number of physical block address storing areas of each scope increases. On the other hand, as the number of divided areas of each of the flash memory chips 2-0 to 2-3 increases, the capacity required for the address translation table 27 decreases because the number of physical block address storing areas of each scope decreases while the access speed becomes slow because the frequency of updating of the address translation table 27 becomes high. Therefore, the number of divided areas of each of the flash memory chips 2-0 to 2-3 should be determine based on the required access speed and memory capacity of the SRAM work area 8.

Furthermore, in the flash memory system 1 according to the above described embodiment, each block is composed of 32 pages. However, the number of pages composing each block is not limited to 32 and can be another number such as 16 or 64.

Further, in the flash memory system 1 according to the above described embodiment, the address translation table 27 is composed of the 4 scopes 0 to 3. However, number of the scopes composing the address translation table 27 is not limited to 4 and can be another number such as 2 or 8. As the number of scopes composing the address translation table 27 decreases, the capacity required for the SRAM work area 8 decreases while the access speed becomes slow because the frequency of updating of the address translation table 27 becomes high. On the other hand, as the number of scopes composing the address translation table 27 increases, the access speed increases because the frequency of updating of the address translation table 27 becomes low while the capacity required for the SRAM work area 8 increases. Therefore, the number of scopes composing the address translation table 27 should be determine based on the required access speed and memory capacity of the SRAM work area 8.

Furthermore, in the flash memory system 1 according to the above described embodiment, the priority order of the scopes 0 to 3 composing the address translation table 27 is determined by the priority link 29. However, the determination of the priority order of the scopes 0 to 3 is not limited to using the priority link 29, and it is possible to use another method for determining the priority order. For example, the priority order can be determined by providing each of the scopes 0 to 3 with a counter for counting the number of accesses and the priority order be based on the count value of the counters.

Further, in the flash memory system 1 according to the above described embodiment, the erased block queue 30 is composed of 8 queues in which 2 queues are assigned for each scope. However, the number of queues assigned for each scope is not limited to 2 and can be another number such as 1 or 4.

Furthermore, in the flash memory system 1 according to the above described embodiment, an erase flag is provided at the redundant area 26 of the top page (page 0) of each block to enable to detection of whether or not each block is an erased block. However, it is not essential to employ the erase flag in the redundant area 26. For example, it is possible to assign “all 1 (1023)” to erased blocks as the corresponding logical block address to indicate the block is an erased block.

Further, in this specification and the appended claims, the respective means need not necessarily be physical means and arrangements whereby the functions of the respective means are accomplished by software fall within the scope of the present invention. In addition, the function of a single means may be accomplished by two or more physical means and the functions of two or more means may be accomplished by a single physical means.

As explained in the foregoing, the present invention provides a memory controller for a flash memory system employing an address translation table which requires relatively small capacity and a method for accessing the flash memory device using the address translation table which requires relatively small capacity.

What is claimed is:

1. A memory controller for accessing a memory divided into a plurality of areas based on a host address supplied from a host computer comprising an address translation table constituted of a plurality of scopes each of which stores a piece of address translating information corresponding to one of said areas of said memory, each piece of said address translating information being composed of a plurality of converted addresses, said memory controller further comprising selecting means for selecting one of said scopes from said address translation table based on a first portion of said host address, reading means for reading out one converted address from said address translation information stored in the selected scope based on a second portion of said host address, and access means for accessing the memory based on at least the thus read-out converted address, the number of said scopes of said address translation table being smaller than that of said areas of said memory.

2. The memory controller as claimed in claim 1, wherein the memory controller further comprises replace means for replacing, in response to the fact that said address translating information corresponding to an area selected by said first portion of said host address is not stored in any scopes of said address translation table, said address translating information stored in one of said scopes with address translating information corresponding to said area selected by said first portion of said host address.

3. The memory controller as claimed in claim 2, wherein the memory controller further comprises scope determination means for determining a scope to be replaced by said replacing means based on an access history.

4. The memory controller as claimed in claim 1, wherein each of said areas is divided into a plurality of blocks each of which is composed of a plurality of flash memory cells, said converted address being used to select one of said blocks, each of said blocks constituting a unit to be flash-erased.

5. The memory controller as claimed in claim 4, wherein said access means accesses said memory based on at least said read-out converted address and a third portion of said host address.

6. The memory controller as claimed in claim 5, wherein each of said blocks is divided into a plurality of pages, said third portion of said host address being used to select one of said pages included in said block selected by said converted address, each of said pages constituting a unit to be accessed.

7. The memory controller as claimed in claim 5, wherein said access means accesses said memory based on at least said read converted address and said first and third portions of said host address.

8. A flash memory system comprising a flash memory and a memory controller for accessing said flash memory based on a host address including at least an area address and a logical block address and supplied from a host computer, said flash memory being divided into a plurality of areas, each of said areas being selected by said area address of said host address and divided into a plurality of blocks, each of said blocks being selected by a physical block address, said memory controller further comprising an address translation table which is divided into a plurality of scopes, a management table storing a relationship between said scopes and said areas of said flash memory, judgment means for judging whether or not address translating information for said area selected by said area address is stored in one of said scopes of said address translation table by referring to said management table, replace means for replacing said address translating information stored in one of said scopes with address translating information for said area selected by said area address when said address translating information for said area selected by said area address is not stored in any scopes of said address translation table, converting means for converting said logical block address of said host address into said physical block address by referring to said scope storing said address translating information for said area selected by said area address, and access means for accessing said flash memory based on at least said logical block address, each of said scopes storing address translating information indicating relationships between said logical block addresses and said physical block addresses, the number of said scopes being smaller than that of said areas of said flash memory.

9. The flash memory system as claimed in claim 8, wherein said flash memory and said memory controller are enclosed in the same package.

10. The flash memory system as claimed in claim 9, wherein said package is card-shaped.

11. The flash memory system as claimed in claim 8, wherein said host address is composed of at least said area address, said logical block address and a page address, and each of said blocks is divided into a plurality of pages which are selected by said page addresses.

12. The flash memory system as claimed in claim 8, wherein each of said blocks constitutes a unit to be flash-erased.

13. The flash memory system as claimed in claim 11, wherein each of said pages constitutes a unit to be accessed.

14. The flash memory system as claimed in claim 13, wherein each of said pages includes a user area and a redundant area, and said redundant area stores an error correction code for correcting an error of user data stored in said user area.

15. The flash memory system as claimed in claim 8, wherein said memory controller further comprises a priority link for indicating which scope is the least significant.

16. The flash memory system as claimed in claim 15, wherein said replacing means replaces said address translating information stored in said scope which is indicated as the least significant scope by said priority link with address translating information for said area selected by the area address.

17. The flash memory system as claimed in claim 8, wherein said flash memory includes a plurality of flash memory cells, each of which can store more than 2 bits.

18. A method for accessing a flash memory divided into m areas comprising the steps of receiving a host address supplied from a host computer, selecting one of n (n<m) scopes constituting an address translation table based on a first portion of said host address, converting a second portion of said host address into a converted address based on address translating information read from the selected scope, and accessing said flash memory based on at least said converted address.

19. The method for accessing a flash memory as claimed in claim 18, wherein the method for accessing a flash memory further comprises the step of replacing said address translating information stored in one of said scopes with address translating information corresponding to said area selected by said first portion of said host address when said address translating information corresponding to an area selected by said first portion of said host address is not stored in any scopes of said address translation table.

20. The method for accessing a flash memory as claimed in claim 19, wherein the method for accessing a flash memory further comprises the step of determining a scope to be replaced during said replacing step based on an access history.
